(19) United States
(12) Patent Application Publication
(10) Pub. No.: US 2026/0268842 A1
(43) Pub. Date: Sep. 10, 2026

(54) Display Substrate and Display Device

(71) Applicants: BOE TECHNOLOGY GROUP CO., LTD., Chaoyang District, Beijing (CN); Chongqing BOE Display Technology Co., Ltd., Chongqing (CN)

(72) Inventors: Rui Wang, Beijing (CN); Xiaoling He, Beijing (CN); Runxin Zhang, Beijing (CN); Ming Hu, Beijing (CN); Shouqiang Zhang, Beijing (CN)

(21) Appl. No.: 18/881,553

(22) PCT Filed: Sep. 6, 2023
(86) PCT No.: PCT/CN2023/117345

§ 371 Date: Jan. 6, 2025

(51) Int. Cl. G09G 3/3225

(52) U.S. Cl. CPC G09G 3/3225; G09G 2300/0426; G09G 2300/043; G09G 2300/0819; G09G 2320/0214; G09G 2320/0233; G09G 2330/021

(57) ABSTRACT

A display substrate includes a plurality of pixel driving circuits and data signal line groups. A column of pixel driving circuits are divided into n pixel driving circuit groups, and a data signal line group is electrically connected to a column of pixel driving circuits. Two data signal line groups respectively electrically connected to an m-th column of pixel driving circuits and an (m+1)-th column of pixel driving circuits include a first data signal line and a second data signal line, located between the two columns of pixel driving circuits. Multiple anode transfer lines electrically connected to the (m+1)-th column of pixel driving circuits include a first anode transfer line including a first anode transfer portion in a same layer as a data signal line. In a row direction, the first anode transfer portion is located between the first data signal line and the second data signal line.

### CROSS-REFERENCE TO RELATED APPLICATION

This application is the United States national phase of International Patent Application No. PCT/CN2023/117345, filed Sep. 6, 2023, the disclosure of which is hereby incorporated by reference in its entirety.

### BACKGROUND OF THE INVENTION

### Field of the Invention

The present disclosure relates to the field of display technologies, and in particular, to a display substrate and a display device.

### Description of Related Art

At present, organic light-emitting diode (OLED) display devices are widely applied due to their advantages such as self-luminous, fast response, wide viewing angle and applicable to be fabricated on a flexible substrate. An OLED display device includes a plurality of sub-pixels, each sub-pixel includes a pixel driving circuit and a light-emitting device, and the light-emitting device is driven by the pixel driving circuit to emit light to achieve the display function.

### SUMMARY OF THE INVENTION

In an aspect, a display substrate is provided. The display substrate includes a substrate and a driving circuit layer located on the substrate. The driving circuit layer includes: a plurality of pixel driving circuits and a plurality of data signal line groups; the plurality of pixel driving circuits are arranged in multiple rows and multiple columns, and a column of pixel driving circuits are divided into n pixel driving circuit groups. A data signal line group is electrically connected to the column of pixel driving circuits, the data signal line group includes n data signal lines extending in a column direction and arranged at intervals in a row direction, and a data signal line is electrically connected to all pixel driving circuits in a pixel driving circuit group. Two adjacent columns of pixel driving circuits are an m-th column of pixel driving circuits and an (m+1)-th column of pixel driving circuits. A data signal line group electrically connected to the m-th column of pixel driving circuits includes at least one first data signal line, and a first data signal line of the at least one first data signal line is located between the m-th column of pixel driving circuits and the (m+1)-th column of pixel driving circuits. A data signal line group electrically connected to the (m+1)-th column of pixel driving circuits includes at least one second data signal line, and a second data signal line of the at least one second data signal line is located between the m-th column of pixel driving circuits and the (m+1)-th column of pixel driving circuits. The driving circuit layer further includes a plurality of anode transfer lines respectively electrically connected to driving output terminals of the plurality of pixel driving circuits; multiple anode transfer lines electrically connected to the (m+1)-th column of pixel driving circuits include at least one first anode transfer line, and a first anode transfer line of the at least one first anode transfer line includes a first anode transfer portion in a same layer as the data signal line. In the row direction, the first anode transfer portion is located between the first data signal line electrically connected to the m-th column of pixel driving circuits and the second data signal line electrically connected to the (m+1)-th column of pixel driving circuits. n is a positive integer greater than or equal to 2, and m is a positive integer.

In some embodiments, the display substrate further includes an anode layer, the anode layer is located on a side of the driving circuit layer away from the substrate. The anode layer includes a plurality of anodes; the plurality of anodes include first anodes and second anodes, and the first anodes and the second anodes are alternately arranged in the column direction. The first anode transfer portion extends in the column direction, and an orthographic projection of the first anode transfer portion on the substrate overlaps with an orthographic projection of a first anode of the first anodes on the substrate; the orthographic projection of the first anode transfer portion on the substrate overlaps with an orthographic projection of a second anode of the second anodes on the substrate, and the first anode transfer portion is electrically connected to the second anode.

In some embodiments, in the column direction, the orthographic projection of the first anode on the substrate and the orthographic projection of the second anode on the substrate are located between orthographic projections of two ends of the first anode transfer portion on the substrate.

In some embodiments, the data signal line group electrically connected to the m-th column of pixel driving circuits includes at least one third data signal line, and a third data signal line of the at least one third data signal line is located on a side of the m-th column of pixel driving circuits away from the (m+1)-th column of pixel driving circuits. Multiple anode transfer lines electrically connected to the m-th column of pixel driving circuits include at least one second anode transfer line, and a second anode transfer line of the at least one second anode transfer line includes a second anode transfer portion in the same layer as the data signal line. In the row direction, the second anode transfer portion is located on the side of the m-th column of pixel driving circuits away from the (m+1)-th column of pixel driving circuits.

In some embodiments, the second anode transfer portion extends in the column direction, and an orthographic projection of the second anode transfer portion on the substrate overlaps with the orthographic projection of the first anode on the substrate, the second anode transfer portion is electrically connected to the first anode, and the orthographic projection of the second anode transfer portion on the substrate overlaps with the orthographic projection of the second anode on the substrate.

In some embodiments, in the column direction, the orthographic projection of the first anode on the substrate and the orthographic projection of the second anode on the substrate are located between orthographic projections of two ends of the second anode transfer portion on the substrate.

In some embodiments, multiple columns of pixel driving circuits further include an (m+2)-th column of pixel driving circuits, and the (m+2)-th column of pixel driving circuits is located on a side of the (m+1)-th column of pixel driving circuits away from the m-th column of pixel driving circuits. The data signal line group electrically connected to the (m+1)-th column of pixel driving circuits further includes at least one fourth data signal line, and a fourth data signal line of the at least one fourth data signal line is located between the (m+1)-th column of pixel driving circuits and the (m+2)-th column of pixel driving circuits. A data signal line group electrically connected to the (m+2)-th column of pixel driving circuits includes at least one fifth data signal line, and a fifth data signal line of the at least one fifth data signal line is located between the (m+1)-th column of pixel driving circuits and the (m+2)-th column of pixel driving circuits. Multiple anode transfer lines electrically connected to the (m+2)-th column of pixel driving circuits include a third anode transfer line, and the third anode transfer line includes a third anode transfer portion in the same layer as the data signal line. In the row direction, the third anode transfer portion is located between the fourth data signal line electrically connected to the (m+1)-th column of pixel driving circuits and the fifth data signal line electrically connected to the (m+2)-th column of pixel driving circuits.

In some embodiments, the plurality of anodes further include third anodes, and in the row direction, a third anode overlaps with the first anode, and the third anode overlaps with the second anode. The third anode transfer portion extends in the column direction; in the column direction, a border of an orthographic projection of the third anode transfer portion on the substrate overlaps with a border of an orthographic projection of the third anode on the substrate, and the third anode transfer portion is electrically connected to the third anode.

In some embodiments, in the column direction, the orthographic projection of the third anode on the substrate is located between orthographic projections of two ends of the third anode transfer portion on the substrate.

In some embodiments, in a same column of pixel driving circuits, a number of pixel driving circuits in each pixel driving circuit group is same.

In some embodiments, multiple data signal lines in the data signal line group are divided into a first part of data signal lines and a second part of data signal lines, and the first part of data signal lines and the second part of data signal lines are respectively located on two sides of the column of pixel driving circuits electrically connected the data signal line group, and a number of data signal lines of the first part is equal to a number of data signal lines of the second part.

In some embodiments, the pixel driving circuit includes: a driving transistor, a data writing transistor, a data transfer portion and a first light-emitting control transistor; a first electrode of the driving transistor and a second electrode of the data writing transistor are electrically connected to a second electrode of the first light-emitting control transistor, and a first electrode of the data writing transistor is electrically connected to a data signal line in the data signal line group through the data transfer portion. In the column direction, the data writing transistor is located on a side of the first light-emitting control transistor away from the driving transistor, and the first electrode of the data writing transistor is located on a side of the data writing transistor away from the first light-emitting control transistor.

In some embodiments, the pixel driving circuit further includes a second light-emitting control transistor and a second reset transistor, and a second electrode of the second light-emitting control transistor is electrically connected to a second electrode of the second reset transistor. In the column direction, the second reset transistor is located on a side of the second light-emitting control transistor away from the driving transistor; in the row direction, the second light-emitting control transistor is adjacent to the first light-emitting control transistor, and the second reset transistor is adjacent to the data writing transistor.

In some embodiments, the column of pixel driving circuits include a first part of pixel driving circuits electrically connected to the second part of data signal lines and a second part of pixel driving circuits electrically connected to the first part of data signal lines. A data writing transistor of the first part of pixel driving circuits is located between a second reset transistor of the first part of pixel driving circuits and the second part of data signal lines, and a data writing transistor of the second part of pixel driving circuits is located on a side of a second reset transistor of the second part of pixel driving circuits away from the first part of data signal lines. At least one pixel driving circuit in the second part of pixel driving circuits includes a first data transfer portion, and in a pixel driving circuit including the first data transfer portion, the first data transfer portion is electrically connected to a first electrode of a data writing transistor and a data signal line; the first data transfer portion includes an avoiding portion, and the avoiding portion is located on a side of a second reset transistor away from a second light-emitting control transistor in the pixel driving circuit including the first data transfer portion.

In some embodiments, the driving circuit layer further includes a second initialization signal line, the second initialization signal line includes a first connecting portion, and a first electrode of the second reset transistor is electrically connected to the first connecting portion of the second initialization signal line. In the column direction, the second initialization signal line is located on a side of the second reset transistor away from the second light-emitting control transistor, and the avoiding portion is located on a side of the first connecting portion away from the second light-emitting control transistor.

In some embodiments, the driving circuit layer further includes a plurality of first power signal lines extending in the column direction and arranged in the row direction, and a first power signal line is electrically connected to the pixel driving circuit. In the row direction, the first part of data signal lines and the second part of data signal lines are respectively located on two sides of the first power signal line.

In some embodiments, the avoiding portion crosses over a first power signal line electrically connected to the second part of pixel driving circuits.

In some embodiments, the data signal line group includes two data signal lines. The driving circuit layer includes a first semiconductor layer, a first gate metal layer, a second gate metal layer, a first wiring metal layer and a second wiring metal layer that are arranged in sequence on the substrate. The two data signal lines in the data signal line group are both located in the second wiring metal layer.

In some embodiments, the data signal line group includes four data signal lines. The driving circuit layer further includes a first semiconductor layer, a first gate metal layer, a second gate metal layer, a first wiring metal layer, a second wiring metal layer and a third wiring metal layer that are arranged in sequence on the substrate. At least a part of data signal lines in the data signal line group is located in the second wiring metal layer, and/or at least a part of data signal lines in the data signal line group is located in the third wiring metal layer.

In another aspect, a display device is provided. The display device includes the display substrate according to any one of the above embodiments.

### BRIEF DESCRIPTION OF THE DRAWINGS

In order to describe the technical solutions in the present disclosure more clearly, the accompanying drawings to be used in some embodiments of the present disclosure will be briefly introduced below. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device, in accordance with some embodiments;

FIG. 2 is a structural diagram of a display substrate, in accordance with some embodiments;

FIG. 3 is a sectional view of a display substrate, in accordance with some embodiments;

FIG. 4 is an equivalent circuit diagram of a plurality of pixel driving circuits in a display substrate, in accordance with some implementations;

FIG. 5 is an equivalent circuit diagram of a pixel driving circuit, in accordance with some embodiments;

FIG. 6 is an equivalent circuit diagram of a plurality of pixel driving circuits in a display substrate, in accordance with some embodiments;

FIG. 7 is a diagram showing a connection between a pixel driving circuit and a light-emitting layer, in accordance with some embodiments;

FIG. 8 is a film layer structural diagram of a first semiconductor layer in FIG. 7;

FIG. 9 is a film layer structural diagram of a first gate metal layer in FIG. 7;

FIG. 10 is a film layer structural diagram of a first semiconductor layer and a first gate metal layer in FIG. 7;

FIG. 11 is a film layer structural diagram of a second gate metal layer in FIG. 7;

FIG. 12 is a film layer structural diagram of a first semiconductor layer, a first gate metal layer, and a second gate metal layer in FIG. 7;

FIG. 13 is a film layer structural diagram of a first wiring metal layer in FIG. 7;

FIG. 14 is a diagram of a first semiconductor layer, a first gate metal layer, a second gate metal layer, and a first wiring metal layer in FIG. 7;

FIG. 15 is a film layer structural diagram of a second wiring metal layer in FIG. 7;

FIG. 16 is a film layer structural diagram of a first semiconductor layer, a first gate metal layer, a second gate metal layer, a first wiring metal layer, and a second wiring metal layer in FIG. 7;

FIG. 17 is a film layer structural diagram of an anode layer, in accordance with some embodiments;

FIG. 18 is a diagram showing a connection between a pixel driving circuit and a light-emitting layer, in accordance with some other embodiments;

FIG. 19 is a film layer structural diagram of a first wiring metal layer in FIG. 18;

FIG. 20 is a film layer structural diagram of a first semiconductor layer, a first gate metal layer, a second gate metal layer, and a first wiring metal layer in FIG. 18;

FIG. 21 is a film layer structural diagram of a second wiring metal layer in FIG. 18;

FIG. 22 is a film layer structural diagram of a first semiconductor layer, a first gate metal layer, a second gate metal layer, a first wiring metal layer, and a second wiring metal layer in FIG. 18;

FIG. 23 is a film layer structural diagram of an anode layer in FIG. 18;

FIG. 24 is an equivalent circuit diagram of a plurality of pixel driving circuits in a display substrate, in accordance with some other embodiments;

FIG. 25 is a diagram showing a partial connection between a pixel driving circuit and a light-emitting layer in the region B1 in FIG. 24;

FIG. 26 is a partial film layer structural diagram in the region B1 of FIG. 24;

FIG. 27 is a diagram showing a partial connection between a pixel driving circuit and a light-emitting layer in the region B2 in FIG. 24;

FIG. 28 is a partial film layer structural diagram in the region B2 in FIG. 24;

FIG. 29 is a diagram showing a partial connection between a pixel driving circuit and a light-emitting layer in the region B3 in FIG. 24;

FIG. 30 is a partial film layer structural diagram in the region B3 in FIG. 24;

FIG. 31 is a diagram showing a partial connection between a pixel driving circuit and a light-emitting layer in the region B4 in FIG. 24; and

FIG. 32 is a partial film layer structural diagram in the region B4 in FIG. 24.

### DESCRIPTION OF THE INVENTION

The technical solutions in some embodiments of the present disclosure will be clearly and completely described below with reference to the accompanying drawings. Obviously, the embodiments to be described are merely some but not all embodiments of the present disclosure. All other embodiments obtained by a person of ordinary skill in the art based on the embodiments of the present disclosure should belong to the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, a feature defined with “first” or “second” may explicitly or implicitly include one or more of the feature. In the description of the embodiments of the present disclosure, the term “a/the plurality of” means two or more unless otherwise specified.

In the description of some embodiments, the terms “coupled” and “connected” and derivatives thereof may be used. The term “connected” should be understood in a broad sense; for example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

As used herein, the term “if”, depending on the context, is optionally construed as “when” or “in a case where”. Similarly, depending on the context, the phrase “if it is determined that” or “if [a stated condition or event] is detected” is optionally construed as “in a case where it is determined that” or “in response to determining that”.

The use of the phrase “applicable to” or “configured to” is meant to be an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value, and the acceptable range of deviation is determined, for example, by a person of ordinary skill in the art, considering measurement in question and errors (i.e., limitations of a measurement system) associated with measurement of a particular quantity.

The term such as “parallel”, “perpendicular” or “equal” as used herein includes a stated condition and a condition similar to the stated condition within an acceptable range of deviation, and the acceptable range of deviation is determined, for example, by a person of ordinary skill in the art, considering measurement in question and errors (i.e., limitations of a measurement system) associated with measurement of a particular quantity. For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°, the term “equal” includes absolute equality and approximate equality, and an acceptable range of deviation of the approximate equality may be, for example, that a difference between two equals is less than or equal to 5% of either of the two equals.

It will be understood that, in a case where a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of the regions in a device, and are not intended to limit the scope of the exemplary embodiments.

For all transistors used in the circuit structures provided in the embodiments of the present disclosure, a first electrode of each transistor is one of a source and a drain, and a second electrode of the transistor is the other of the source and the drain. Since the source and the drain of the transistor may be symmetrical in structure, there may be no difference in structure between the source and the drain of the transistor; that is, there may be no difference in structure between the first electrode and the second electrode of the transistor in the embodiments of the present disclosure.

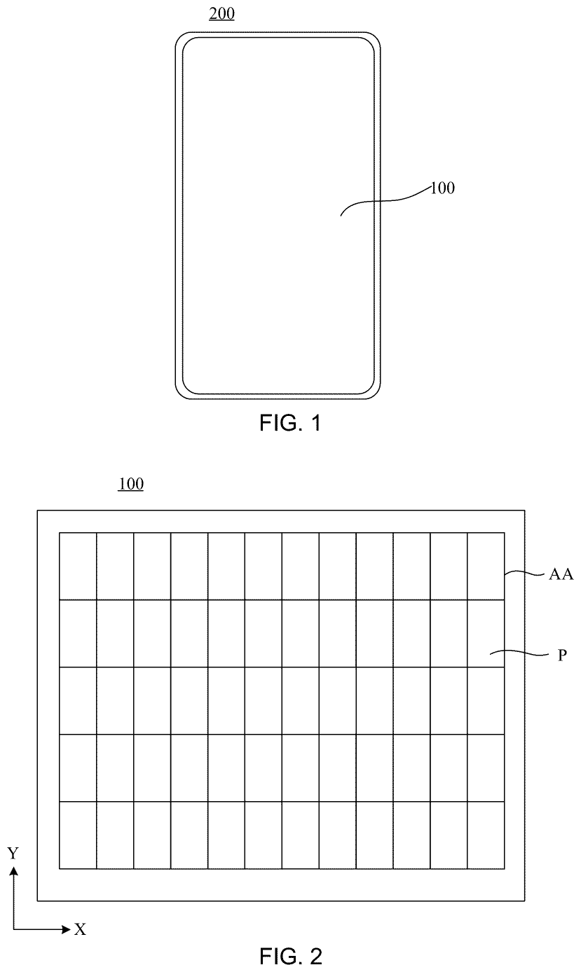

FIG. 1 is a structural diagram of a display device, in accordance with some embodiments. With reference to FIG. 1, some embodiments of the present disclosure provide a display device 200, and the display device 200 includes a display substrate 100.

For example, the display device 200 may further include a frame and other electronic components.

For example, the display device 200 may be an electroluminescent display device or a photoluminescent display device. In a case where the display device is the electroluminescent display device, the electroluminescent display device may be an organic light-emitting diode (OLED) display device or a quantum dot light-emitting diode (QLED) display device. In a case where the display device is the photoluminescent display device, the photoluminescent display device may be a quantum dot photoluminescent display device.

For example, the display device 200 may be any display device that displays images whether in motion (e.g., videos) or stationary (e.g., static images), and whether textual or graphical. More specifically, it is expected that the display device in the embodiments may be implemented in or associated with a variety of electronic devices, and the variety of electronic devices include (but are not limit to), for example, mobile phones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (e.g., odometer displays), navigators, cockpit controllers and/or displays, camera view displays (e.g., rear view camera displays in vehicles), electronic photos, electronic billboards or indicators, projectors, building structures, packagings and aesthetic structures (e.g., a display for an image of a piece of jewelry), etc.

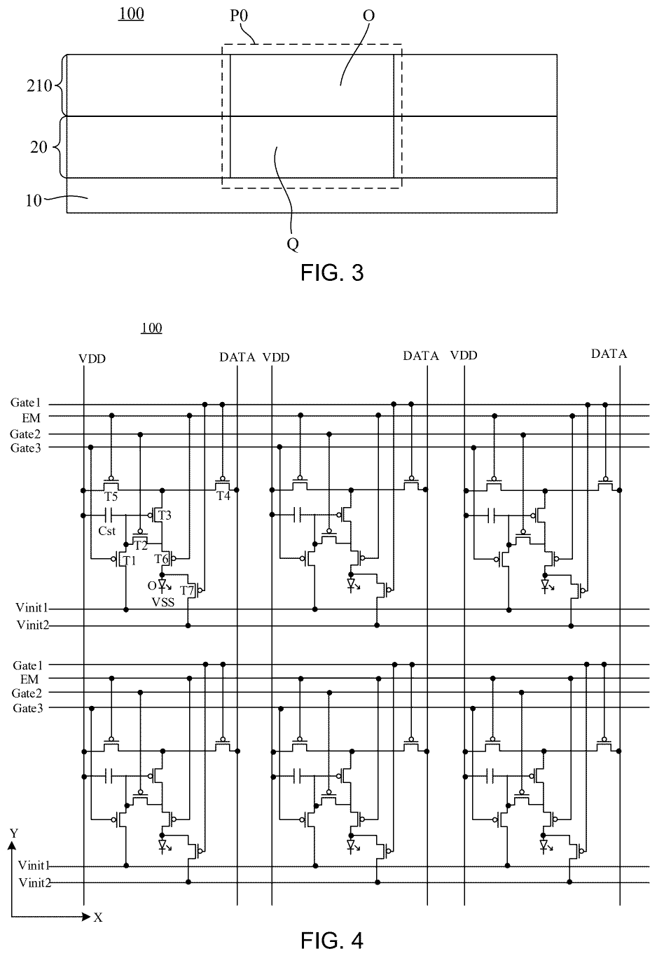

FIG. 2 is a structural diagram of a display substrate, in accordance with some embodiments; FIG. 3 is a sectional view of a display substrate, in accordance with some embodiments.

Some embodiments of the present disclosure provide a display substrate 100. Referring to FIGS. 2 and 3, the display substrate 100 includes an active area AA (may also be referred to as an effective display area). The active area AA includes a plurality of pixel regions P, and the plurality of pixel regions P may be arranged in an array.

For example, the plurality of pixel regions P may include a plurality of sub-pixel regions PO, and one sub-pixel region PO corresponds to a minimum unit for the display substrate 100 to display an image. The plurality of sub-pixel regions may include first sub-pixel regions, second sub-pixel regions and third sub-pixel regions. The first sub-pixel regions, the second sub-pixel regions and the third sub-pixel regions respectively emit three primary colors; for example, the first sub-pixel regions may emit red light, the second sub-pixel regions may emit green light, and the third sub-pixel regions may emit blue light. On this basis, by adjusting the luminance (grayscale) of sub-pixel regions of different colors, it is possible to achieve display of multiple colors through color combination and color superimposition, thereby achieving full-color display of the display substrate 100.

In some examples, a sub-pixel region includes a pixel driving circuit Q and a light-emitting device O electrically connected to the pixel driving circuit Q. The pixel driving circuit Q may be adjusted based on various types of signal lines to generate a driving signal, and each light-emitting device O may emit light due to the driving effect of the driving signal generated by a respective pixel driving circuit Q. Based on this, the light-emitting devices O are driven by the respective pixel driving circuits Q in the plurality of sub-pixel regions to emit light, so that the display substrate 100 displays images in the active area AA.

With continued reference to FIGS. 2 and 3, the display substrate 100 further includes a substrate 10, and a driving circuit layer 20 and a light-emitting device layer 210 stacked on the substrate 10. The driving circuit layer 20 may include a plurality of pixel driving circuits Q. The light-emitting device layer 210 is located on a side of the driving circuit layer 20, the light-emitting device layer 210 includes a plurality of light-emitting devices O, and a light-emitting device O is electrically connected to a pixel driving circuit Q in the driving circuit layer 20.

In some examples, the substrate 10 may be a flexible substrate. For example, a material of the substrate 10 may be an organic material. For instance, the material of the substrate 10 may be any one of polyimide (PI), polycarbonate (PC) or polyvinyl chloride (PVC).

In some other examples, the substrate 10 may be a rigid substrate. For example, the rigid substrate may be a glass substrate, a polymethyl methacrylate (PMMA) substrate, or the like.

In some examples, the light-emitting device O includes an anode, a light-emitting portion and a cathode that are sequentially stacked. In some examples, an electron transporting portion is provided between the cathode and the light-emitting portion, and a hole transporting portion is provided between the anode and the light-emitting portion. As an example, the light-emitting device O may be an OLED light-emitting device, but is not limited thereto. The type of the light-emitting device is not limited in the embodiments of the present disclosure; that is, the light-emitting device O may be any other light-emitting devices (e.g., a light-emitting device that emits light by discharging), as long as they are capable of emitting light to enable the display substrate 100 to display images.

In some examples, the plurality of pixel driving circuits Q may be coupled to the plurality of light-emitting devices O in one-to-one correspondence. In some other examples, one pixel driving circuit Q may be coupled to multiple light-emitting devices O, or multiple pixel driving circuits Q may be coupled to one light-emitting device O.

Hereinafter, the structure of the display substrate 100 will be exemplarily described in the embodiments of the present disclosure by taking an example in which one pixel driving circuit Q is coupled to one light-emitting device O.

FIG. 4 is an equivalent circuit diagram of a plurality of pixel driving circuits in a display substrate, in accordance with some implementations.

In some examples, referring to FIGS. 3 and 4, the driving circuit layer 20 is located on a side of the substrate 10. The driving circuit layer 20 includes a plurality of pixel driving circuits Q and a plurality of data signal lines Data. A data signal line Data drives a column of pixel driving circuits Q, and the data signal line is configured to provide a data writing signal to the pixel driving circuits Q.

The plurality of pixel driving circuits Q are arranged in multiple rows and columns. For convenience of description, the plurality of pixel driving circuits Q are described in the embodiments of the present disclosure by taking an example in which the plurality of pixel driving circuits Q are arranged in a matrix.

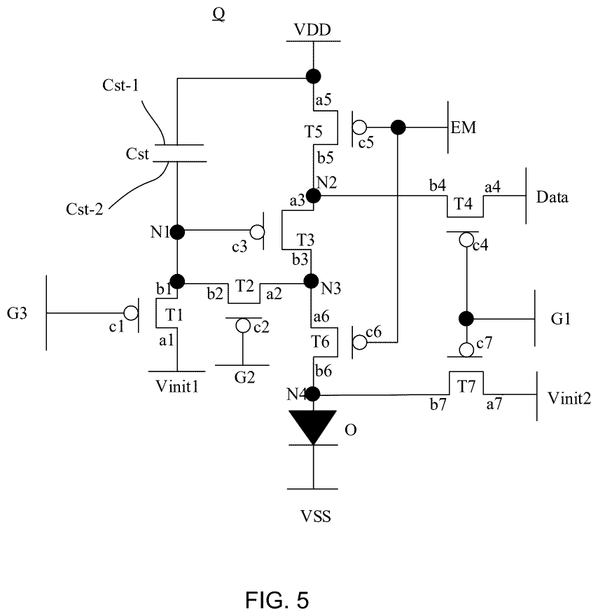

FIG. 5 is an equivalent circuit diagram of a pixel driving circuit, in accordance with some embodiments.

In some examples, as shown in FIG. 5, the pixel driving circuit Q may be a “7T1C” or “8T1C” pixel driving circuit Q, where “T” represents a thin film transistor, the number before “T” represents the number of thin film transistors; “C” represents a storage capacitor Cst, and the number before “C” represents the number of storage capacitors Cst.

In some embodiments, as shown in FIG. 5, the pixel driving circuit Q may be a “7T1C” pixel driving circuit Q. The pixel driving circuit Q may include: a first reset transistor T1, a compensation transistor T2, a driving transistor T3, a data writing transistor T4, a first light-emitting control transistor T5, a second light-emitting control transistor T6, a second reset transistor T7 and a capacitor Cst.

The pixel driving circuit Q needs to be electrically connected to various types of signal lines, and FIG. 5 illustrates various types of signal lines. The various types of signal lines may include: a first scanning signal line G1, a second scanning signal line G2, a data signal line Data, an enable signal line EM, a first power signal line VDD, a third scanning signal line G3, a first initialization signal line Vinit1 and a second initialization signal line Vinit2.

For the connection of the pixel driving circuit to the first scanning signal line G1, the second scanning signal line G2, the data signal line Data, the enable signal line EM, the first power signal line VDD, the third scanning signal line G3, the first initialization signal line Vinit1 and the second initialization signal line Vinit2, reference may be made to FIG. 4, and for the arrangement of the first scanning signal line G1, the second scanning signal line G2, the data signal line Data, the enable signal line EM, the first power signal line VDD, the third scanning signal line G3, the first initialization signal line Vinit1 and the second initialization signal line Vinit2 in the driving circuit layer 20, detailed description will be made in the following.

A control electrode c1 of the first reset transistor T1 is electrically connected to the third scanning signal line G3, a first electrode a1 of the first reset transistor T1 is electrically connected to the first initialization signal line Vinit1, and a second electrode b1 of the first reset transistor T1 is electrically connected to a first node N1.

A control electrode c2 of the compensation transistor T2 is electrically connected to the second scanning signal line G2, a first electrode a2 of the compensation transistor T2 is electrically connected to a third node N3, and a second electrode b2 of the compensation transistor T2 is electrically connected to the first node N1.

In some examples, the second scanning signal line G2 for driving the pixel driving circuits Q in the n-th row may also serve as the third scanning signal line G3 of the pixel driving circuits Q in the (n+7)-th row. Based on this, when the second scanning signal line G2 drives the compensation transistors T2 of the pixel driving circuits Q in the n-th row to be turned on, the second scanning signal line G2 may also drive the first reset transistors T1 of the pixel driving circuits Q in the (n+7)-th row to reset the first nodes N1.

As an example, the second scanning signal line G2 for driving the pixel driving circuits Q in the n-th row includes two branches, and the two branches are a first branch and a second branch. The first branch of the second scanning signal line G2 of the pixel driving circuits Q in n-th row is electrically connected to the pixel driving circuits Q in the n-th row, so as to drive the compensation transistors T2 of the pixel driving circuits Q in the n-th row to be turned on. The second branch of the second scanning signal line G2 of the pixel driving circuits Q in the n-th row is electrically connected to the pixel driving circuits Q in the (n+7)-th row, so as to drive the first reset transistors T1 of the pixel driving circuits Q in the (n+7)-th row to be turned on to reset the first nodes N1.

On this basis, there is no need to separately provide a third scanning signal line G3, which may reduce the number of wirings in the display substrate 100 and facilitate the layout of other wirings in the display substrate 100.

A control electrode c3 of the driving transistor T3 is electrically connected to the first node N1, a first electrode a3 of the driving transistor T3 is electrically connected to a second node N2, and a second electrode b3 of the driving transistor T3 is electrically connected to the third node N3.

A control electrode c4 of the data writing transistor T4 is electrically connected to the first scanning signal line G1, a first electrode a4 of the data writing transistor T4 is electrically connected to the data signal line Data, and a second electrode b4 of the data writing transistor T4 is electrically connected to the second node N2.

A control electrode c5 of the first light-emitting control transistor T5 is electrically connected to the enable signal line EM, a first electrode a5 of the first light-emitting control transistor T5 is electrically connected to the first power signal line VDD, and a second electrode b5 of the first light-emitting control transistor T5 is electrically connected to the second node N2.

A control electrode c6 of the second light-emitting control transistor T6 is electrically connected to the enable signal line EM, a first electrode a6 of the second light-emitting control transistor T6 is electrically connected to the third node N3, a second electrode b6 of the second light-emitting control transistor T6 is electrically connected to a fourth node N4, and the fourth node N4 is electrically connected to the anode of the light-emitting device O. The cathode of the light-emitting device O is electrically connected to a second power signal line VSS. A voltage value of a second power signal provided by the second power signal line VSS is less than a voltage value of a first power signal provided by the first power signal line VDD.

A control electrode c7 of the second reset transistor T7 is electrically connected to a second reset signal line, a first electrode a7 of the second reset transistor T7 is electrically connected to the second initialization signal line Vinit2, a second electrode b7 of the second reset transistor T7 is electrically connected to the fourth node N4, and the fourth node N4 is electrically connected to the anode of the light-emitting device O.

For the storage capacitor Cst, a second plate Cst-2 of the storage capacitor Cst is electrically connected to the control electrode c3 of the driving transistor T3, and a first plate Cst-1 of the storage capacitor Cst is electrically connected to the first power signal line VDD.

In some examples, the second reset signal line and the first scanning signal line G1 may respond to a same signal line, which may be understood as that the first scanning signal line G1 also serves as the second reset signal line. On this basis, the fourth node N4 (the anode of the light-emitting device O) may be reset by the second reset transistor T7 in the data writing phase; that is, the fourth node N4 (the anode of the light-emitting device O) may be reset before the light-emitting phase, which is conducive to improving the brightness uniformity of the display substrate 100. In addition, the first scanning signal line G1 also serving as the second reset signal line may reduce the number of signal lines in the display substrate 100, which is conducive to simplifying the layout of the wirings in the display substrate 100.

It will be noted that, each sub-pixel in the display device 200 is driven by multiple transistors (TFTs) to emit light, and TFT driving technology may be employed to improve display speed, contrast, brightness, and resolution. However, a hysteresis effect exists in TFT. The hysteresis effect of TFT is an uncertainty in the electrical characteristics of TFT that appears under a certain bias voltage. That is, the current flowing through the TFT is not only related to the current bias voltage, but also related to the state of the TFT at the previous moment. The hysteresis effect of TFT is related to the gate dielectric, the semiconductor material and the interface state traps between the gate dielectric and the semiconductor material. In the light-emitting phase, the hysteresis effect of TFT will cause a tendency of current decrease within a frame, which will be perceived by human eyes as flickering and thus affects the display quality of the display device 200.

In order to alleviate the hysteresis effect of the driving transistor T3 in the pixel driving circuit Q, a threshold voltage of a pixel circuit is generally compensated to improve the brightness uniformity of the entire display screen. The threshold voltage of the pixel circuit may be compensated in data writing.

In some embodiments, a driving process of the pixel driving circuit Q shown in FIG. 5 is as follows: a period of a frame includes an initialization phase, a writing phase and a light-emitting phase.

In the initialization phase, a first reset signal transmitted by the third scanning signal line G3 is an effective signal, and in this case the first reset transistor T1 is turned on, so as to transmit a first initialization signal transmitted by the first initialization signal line Vinit1 to the first node N1 to reset the first node N1, which helps to improve the stability of the driving transistor T3 included in the first type pixel driving circuit.

In the writing phase, a second scanning signal transmitted by the second scanning signal line G2 is an effective signal, and the compensation transistor T2 is turned on. In addition, a first scanning signal transmitted by the first scanning signal line G1 is an effective signal, in this case the data writing transistor T4 is turned on, and a data writing signal transmitted by the data signal line Data may be transmitted to the first node N1 sequentially through the data writing transistor T4, the driving transistor T3, and the compensation transistor T2 to compensate the first node N1, and a potential of the first node N1 gradually rises to Vdata+Vth.

Vdata is a voltage value of the data writing signal provided by the data signal line Data, and Vth is the threshold voltage of the driving transistor T3 in a first type of pixel driving circuit. When the potential of the first node N1 is Vdata+Vth, the charging process is completed. Subsequently, the storage capacitor Cst is discharged to keep the driving transistor T3 included in the first type of pixel driving circuit continuously turned on, so as to ensure that the light-emitting device O emits light.

In the light-emitting phase, an enable signal transmitted by the enable signal line EM is an effective signal, and in this case the first light-emitting control transistor T5 and the second light-emitting control transistor T6 are both turned on. In this case, the storage capacitor Cst is discharged to keep the driving transistor T3 included in the first type of pixel driving circuit continuously turned on.

On this basis, a power signal at a constant voltage provided by the first power signal line VDD may sequentially flow through the first light-emitting control transistor T5, the driving transistor T3, and the second light-emitting control transistor T6 to the anode of the light-emitting device O, and the cathode of the light-emitting device O may be electrically connected to the second power signal line VSS, thereby driving the light-emitting device O to emit light. The first power signal line VDD may be a high voltage signal line, and the second power signal line VSS may be a low voltage signal line.

It will be noted that, the term “effective signal” refers to a signal that can enable a transistor to be turned on. For example, the first scanning signal line G1 is electrically connected to a P-type transistor, and the effective signal is a low voltage signal; alternatively, the first scanning signal line G1 is electrically connected to an N-type transistor, and the effective signal is a high voltage signal, and the same is true for other signal lines.

In some examples, the above 7 transistors may all be set as a P-type transistor.

In the case where the above 7 transistors are all P-type transistors, the “effective signal” may be understood as a low voltage signal. That is, the above 7 transistors may all be turned on under control of a low-level signal.

In some examples, the above 7 transistors may all be set as a low temperature polycrystalline silicon (LTPS) transistor. That is, the first reset transistor T1, the compensation transistor T2, the driving transistor T3, the data writing transistor T4, the first light-emitting control transistor T5, the second light-emitting control transistor T6 and the second reset transistor T7 are all low temperature polycrystalline silicon transistors.

In some examples, the first reset transistor T1 and the compensation transistor T2 may be N-type transistors. N-type transistors may help to reduce the risk of current leakage of the transistors. That is, it helps to reduce the risk of current leakage of the first reset transistor T1 and the compensation transistor T2, and helps to ensure the stability of the voltage of the first node N1, i.e., the stability of the driving transistor T3, so as to improve the brightness maintenance rate of the light-emitting device O within a frame.

In the case where the first reset transistor T1 and the compensation transistor T2 are N-type transistors, the above “effective signal” may be understood as a high voltage signal. That is, the first reset transistor T1 and the compensation transistor T2 may be turned on under control of the high voltage signal.

In some examples, the first reset transistor T1 and the compensation transistor T2 may be indium gallium zinc oxide (IGZO) transistors. Oxide transistors have a small off-state leakage current, which reduces the current leakage of the first reset transistor T1 passing through the first node N1 in the light-emitting phase.

In some other embodiments, the pixel driving circuit Q is an “8T1C” pixel driving circuit Q. In this case, the pixel driving circuit Q further includes a third reset transistor. A control electrode of the third reset transistor is electrically connected to a third reset signal line, a first electrode of the third reset transistor is electrically connected to a third initialization signal line, and a second electrode of the third reset transistor is electrically connected to the second node N2.

In some examples, the third reset transistor may be a P-type transistor.

In some examples, the third reset signal line and the second reset signal line may respond to a same signal line, which may also be understood as that the second reset signal line also serves as the third reset signal line.

In some other examples, the third reset signal line and the second reset signal line may respond to different signal lines.

For example, a third initialization signal transmitted by the third initialization signal line may be a high voltage signal. Thus, the high voltage signal may be used to reset the second node N2, which is equivalent to resetting the first electrode of the driving transistor T3, so that an initial state of the driving transistor T3 before the data writing phase is fixed.

As a result, it helps to set the driving transistor T3 in a stable state during the data writing phase, thereby greatly alleviating the hysteresis effect of the driving transistor T3.

The inventors have found through researches that when the display substrate 100 is in operation, a column of pixel driving circuits Q are driven by a same data signal line Data; that is, one data signal line Data drives one column of sub-pixel regions PO, then a refresh duration of any sub-pixel region PO in a column of sub-pixel regions PO is

$$\frac{1}{FH} ,$$

where F is the refresh rate of the display substrate 100, and H is the number of rows of the pixel driving circuits Q in the display substrate 100.

On this basis, in a case where the display substrate 100 is driven at a high refresh rate, the row period of the display substrate 100 becomes short; that is, the row period of each pixel driving circuit Q becomes short, which makes the refresh duration of the pixel driving circuit Q short, causing the duration of the writing phase to become short; that is, the time of threshold compensation for the pixel driving circuit Q becomes short, and the effect of the threshold compensation for the pixel driving circuit Q is poor, which will lead to poor display uniformity of the display substrate 100.

In some examples, “high refresh rate” may be a frequency higher than 120 Hz. As an example, the value range of the high refresh rate may be any one of 120 Hz to 240 Hz, 120 Hz to 300 Hz, or 120 Hz to 480 Hz.

The description will be made by taking an example in which the refresh rate of the display substrate 100 is approximately 240 Hz: the refresh duration of a pixel driving circuit Q is approximately

$$\frac{1}{240 H} ,$$

the refresh duration of the pixel driving circuit Q is short, and the charging time is also short, which may easily lead to the incomplete threshold compensation for the pixel driving circuit Q, affecting the display uniformity of the display substrate 100.

For example, the description will be made by taking a 16-inch display substrate 100 with a resolution of 2560*1600 as an example, the refresh duration of each pixel driving circuit Q is about 1.6 μs. It can be known from this that the display substrate 100 has a high resolution and a high refresh rate, which will cause the refresh duration of the pixel driving circuit Q to be short. Thus, the pixel driving circuit Q will not have sufficient time to perform threshold compensation, which may easily lead to poor display uniformity of the display substrate 100.

Moreover, as consumers' demands for display become more and more demanding, the requirements for the refresh rate and resolution of the display substrate 100 are becoming higher and higher, which will cause the refresh duration of each sub-pixel (the pixel driving circuit Q) to become shorter and shorter, and the charging time to become shorter and shorter. As a result, it is difficult to compensate the threshold voltage within a limited charging time, which will lead to a poor display effect.

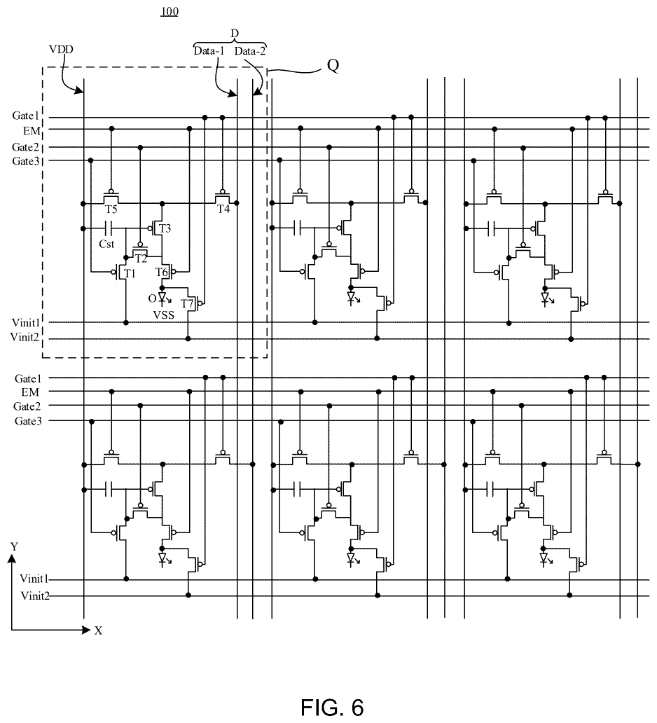

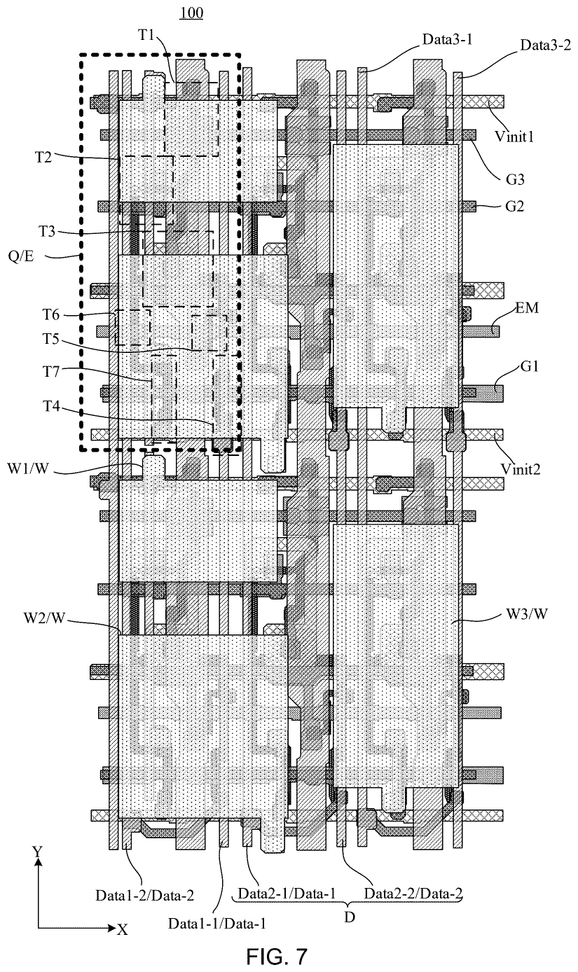

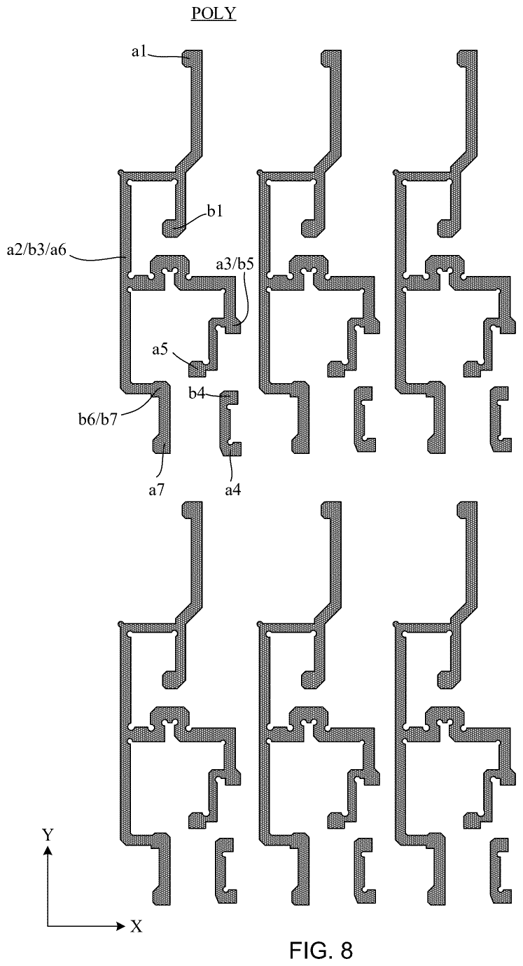

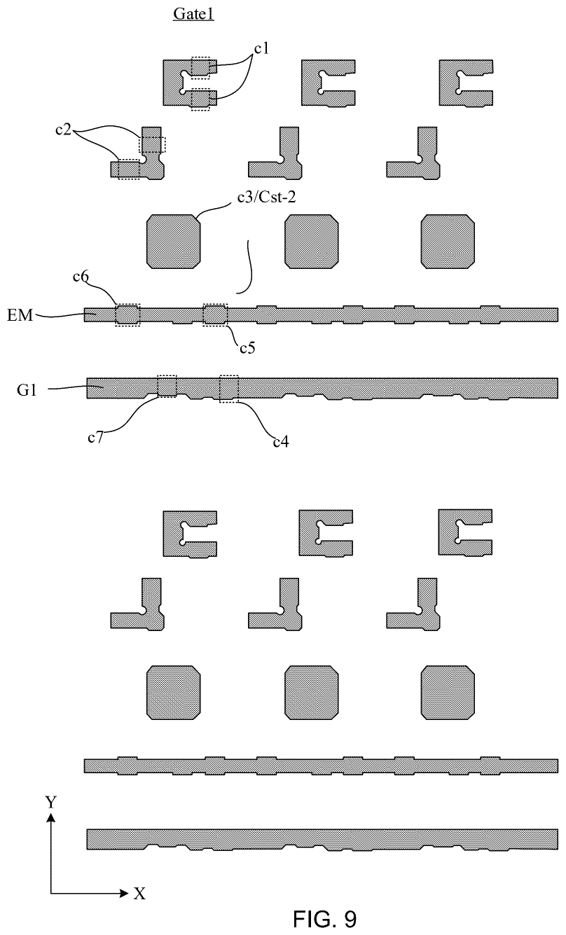

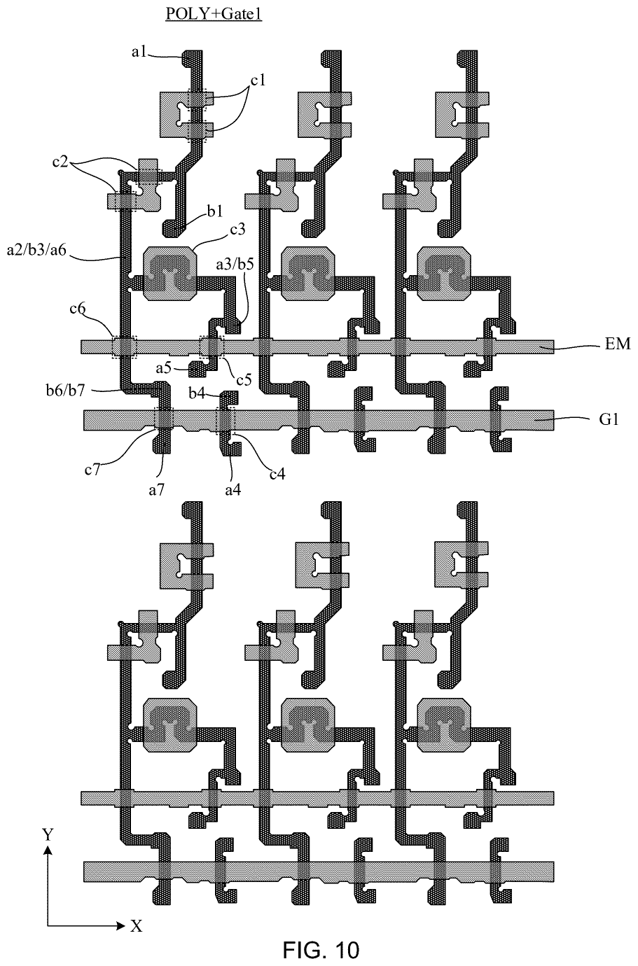

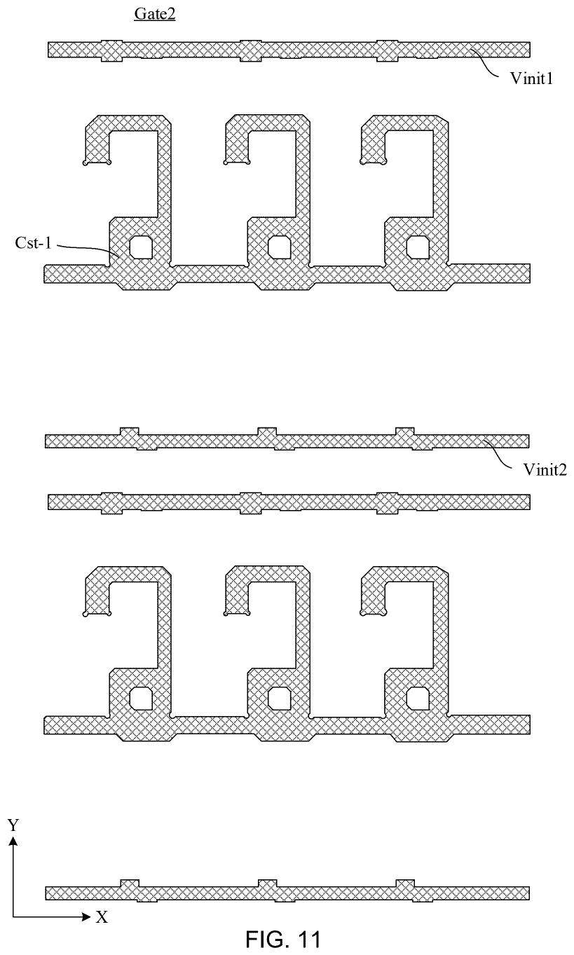

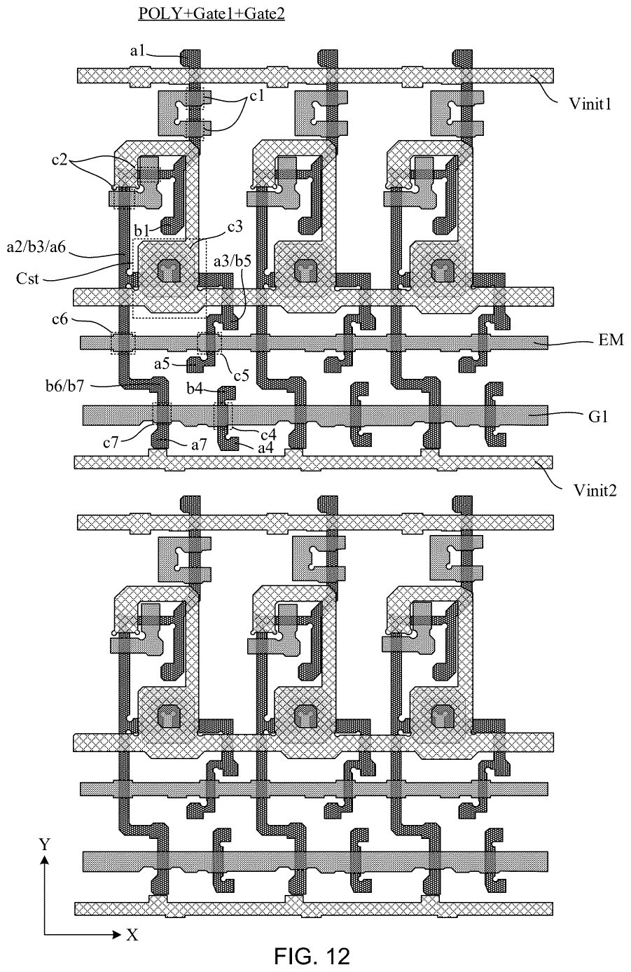

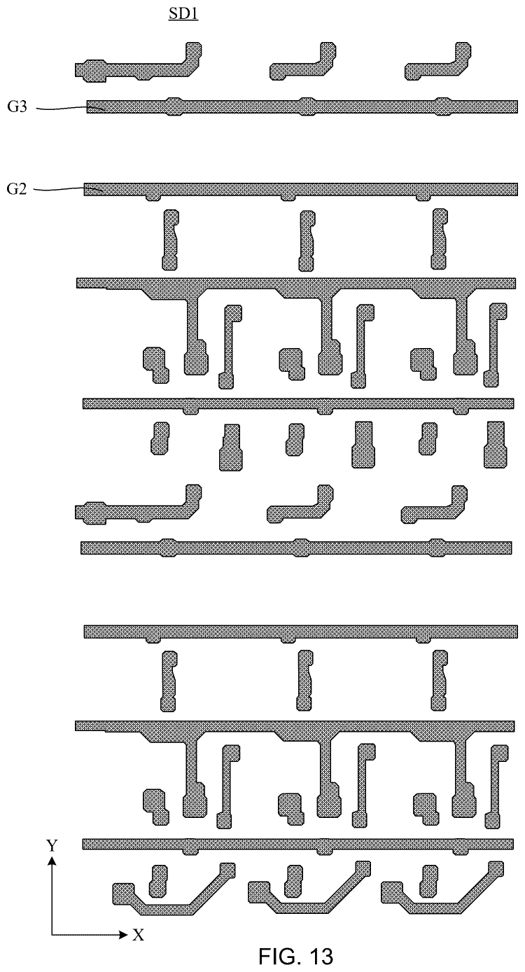

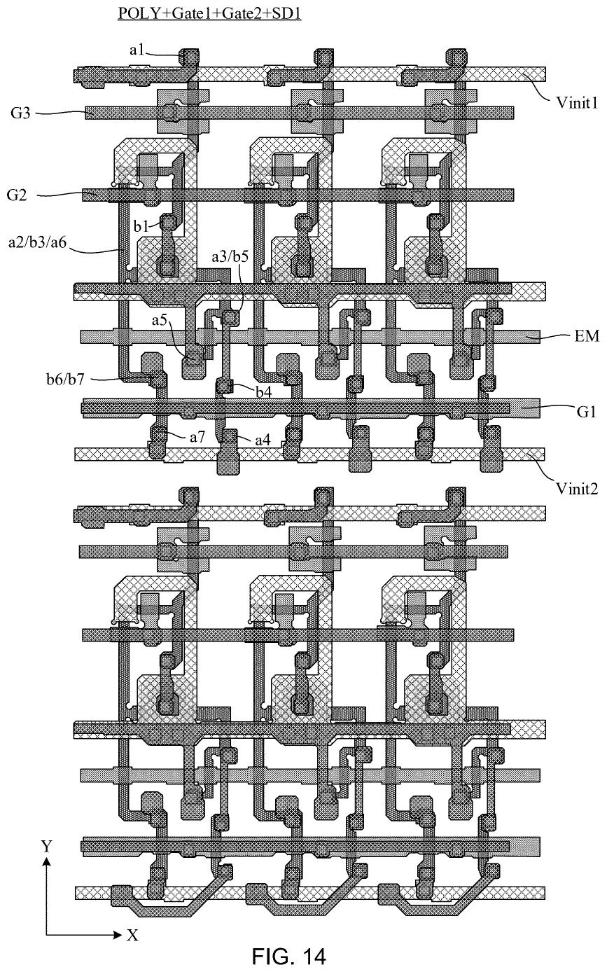

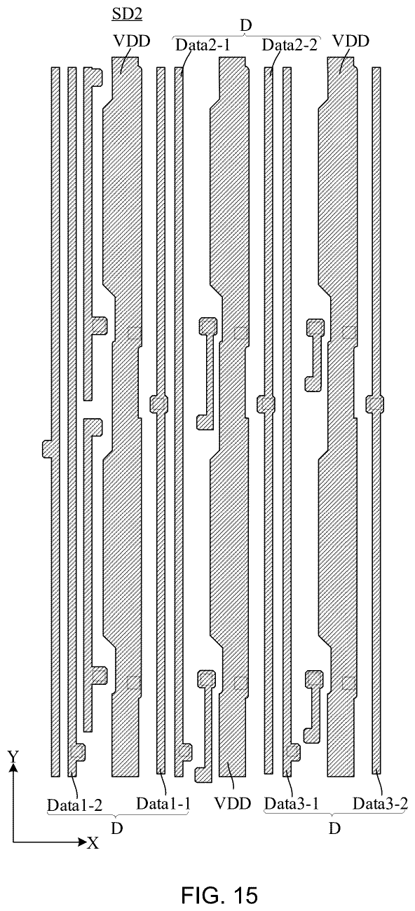

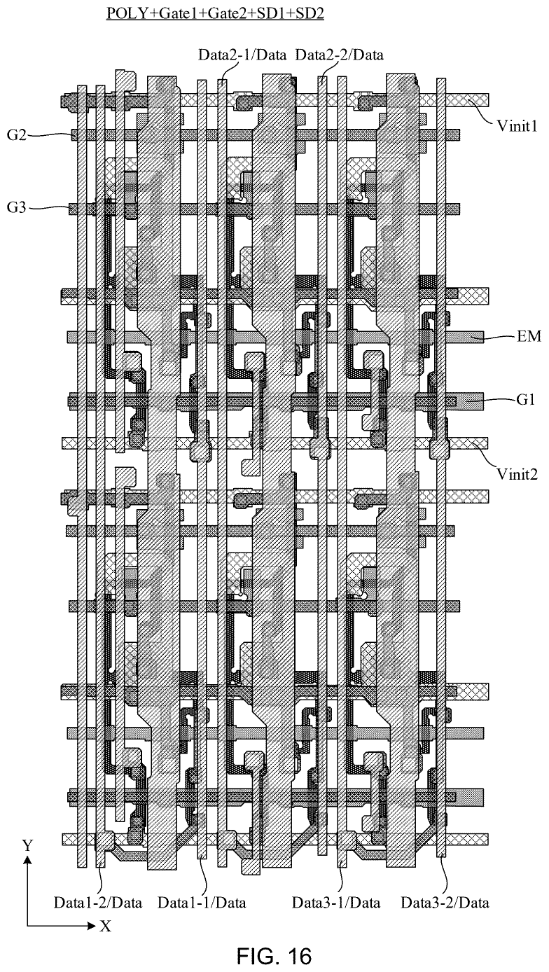

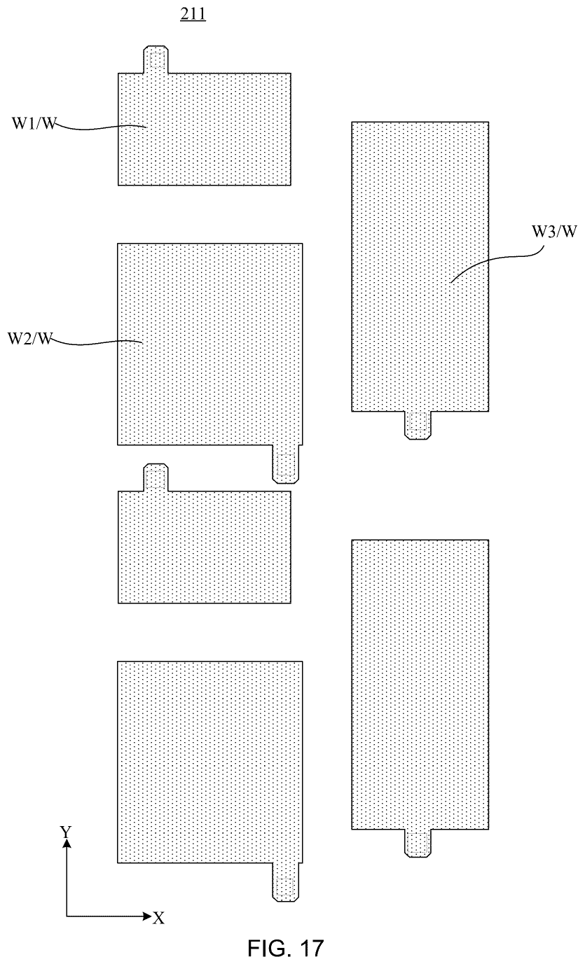

FIG. 6 is an equivalent circuit diagram of a plurality of pixel driving circuits in a display substrate, in accordance with some embodiments; FIG. 7 is a diagram showing a connection between a pixel driving circuit and a light-emitting layer, in accordance with some embodiments; FIG. 8 is a film layer structural diagram of a first semiconductor layer in FIG. 7; FIG. 9 is a film layer structural diagram of a first gate metal layer in FIG. 7; FIG. 10 is a film layer structural diagram of a first semiconductor layer and a first gate metal layer in FIG. 7; FIG. 11 is a film layer structural diagram of a second gate metal layer in FIG. 7; FIG. 12 is a film layer structural diagram of a first semiconductor layer, a first gate metal layer, and a second gate metal layer in FIG. 7; FIG. 13 is a film layer structural diagram of a first wiring metal layer in FIG. 7; FIG. 14 is a film layer structural diagram of a first semiconductor layer, a first gate metal layer, a second gate metal layer, and a first wiring metal layer in FIG. 7; FIG. 15 is a film layer structural diagram of a second wiring metal layer in FIG. 7; FIG. 16 is a film layer structural diagram of a first semiconductor layer, a first gate metal layer, a second gate metal layer, a first wiring metal layer, and a second wiring metal layer in FIG. 7; FIG. 17 is a film layer structural diagram of an anode layer, in accordance with some embodiments.

It will be noted that, in order to clearly illustrate the structure of each pixel driving circuit, FIGS. 6 and 7 schematically illustrate pixel driving circuits Q of 2 rows and 3 columns rather than all the pixel driving circuits Q in the display substrate 100. That is, FIG. 7 shows 6 pixel driving circuits and the data signal lines Data electrically connected thereto.

On this basis, referring to FIGS. 6 to 17, a driving circuit layer 20 of a display substrate 100 provided in some embodiments of the present disclosure includes a first semiconductor layer POLY, a first gate metal layer Gate1, a second gate metal layer Gate2, a first wiring metal layer SD1 and a second wiring metal layer SD2 that are arranged in sequence on the substrate 10.

As shown in FIGS. 7, 8 and 10, the first semiconductor layer POLY is located on the substrate 10, and the first semiconductor layer POLY may include the first electrodes and second electrodes of 7 transistors in the above-mentioned “7T1C” pixel driving circuit. For example, the first semiconductor layer POLY includes the first electrode a4 and the second electrode b4 of the data writing transistor T4. For the case of the “8T1C” pixel driving circuit Q, the first semiconductor layer POLY includes the first electrode and the second electrode of the third reset transistor.

In some examples, a material of the first semiconductor layer POLY may include an amorphous silicon semiconductor material, a monocrystalline silicon semiconductor material, or a polycrystalline silicon semiconductor material.

As shown in FIGS. 7, 9 and 10, the first gate metal layer Gate1 is located on a side of the first semiconductor layer POLY away from the substrate 10. The first gate metal layer Gate1 may include the control electrodes of 7 transistors in the above-mentioned “7T1C” pixel driving circuit. For example, the first gate metal layer Gate1 includes the control electrode of the data writing transistor T4. For the case of the “8T1C” pixel driving circuit Q, the first gate metal layer Gate1 further includes the control electrode of the third reset transistor.

For example, a material of the first gate metal layer Gate1 includes conductive metal. The conductive metal includes at least one of aluminum, copper, or molybdenum, and the present disclosure is not limited thereto.

For example, a first gate insulating layer is provided between the first semiconductor layer POLY and the first gate metal layer Gate1, and the first gate insulating layer electrically insulates the first semiconductor layer POLY from the first gate metal layer Gate1.

For example, a material of the first gate insulating layer includes any one of inorganic insulating materials of silicon nitride, silicon oxynitride and silicon oxide. The material of the first gate insulating layer may include silicon dioxide, and the present disclosure is not limited thereto.

In addition, the first gate metal layer Gate1 may also be used to form a plurality of first scanning signal lines G1 extending in a row direction X and arranged in a column direction Y and a plurality of enable signal lines EM extending in the row direction X and arranged in the column direction Y.

On this basis, the first scanning signal line G1 may include a first portion and a second portion. The first portion of the first scanning signal line G1 may also serve as the control electrode c4 of the data writing transistor T4, and the second portion of the first scanning signal line G1 may also serve as the control electrode c7 of the second reset transistor T7.

The enable signal line EM may include a first portion and a second portion. The first portion of the enable signal line EM may also serve as the control electrode c5 of the first light-emitting control transistor T5, and the second portion of the enable signal line EM may also serve as the control electrode c6 of the second light-emitting control transistor T6.

It will be noted that, an orthographic projection of the first semiconductor layer POLY on the substrate 10 overlaps with an orthographic projection of the first gate metal layer Gate1 on the substrate 10. The portions of the first semiconductor layer POLY that are covered by the first gate metal layer Gate1 constitute the channel portions of all the transistors, and the portions of the first semiconductor layer POLY that are not covered by the first gate metal layer Gate1 are conductive portions, which constitute the first electrodes or the second electrodes of all the transistors.

Referring to FIGS. 7, 11 and 12, the second gate metal layer Gate2 is located on a side of the first gate metal layer Gate1 away from the first semiconductor layer POLY.

For example, a material of the second gate metal layer Gate2 may be the same as the material of the first gate metal material Gate1. It will be understood that, in some other examples, the material of the second gate metal layer Gate2 may be different from the material of the first gate metal material Gate1, which is not limited in the embodiments of the present disclosure.

As an example, a second gate insulating layer is provided between the second gate metal layer Gate2 and the first gate metal layer Gate1. The second gate insulating layer electrically insulates the second gate metal layer Gate2 from the first gate metal layer Gate1.

For example, a material of the second gate insulating layer includes any one of inorganic insulating materials of silicon nitride, silicon oxynitride and silicon oxide. The material of the second gate insulating layer may include silicon dioxide, and the present disclosure is not limited thereto.

In addition, the second gate metal layer Gate2 may also be used to form a plurality of first initialization signal lines Vinit1 extending in the row direction X and arranged in the column direction Y and a plurality of second initialization signal lines Vinit2 extending in the row direction X and arranged in the column direction Y.

Furthermore, the second plate Cst-2 of the storage capacitor Cst may be located in the first gate metal layer Gate1, and the first electrode Cst-1 of the storage capacitor Cst is located in the second gate metal layer Gate2. An orthographic projection of the second plate Cst-2 of the storage capacitor Cst on the substrate 10 at least partially overlaps with an orthographic projection of the first plate Cst-1 of the storage capacitor Cst on the substrate 10 to constitute the storage capacitor Cst.

The second electrode Cst-2 of the storage capacitor Cst located in the first gate metal layer Gate1 may also serve as the control electrode c3 of the driving transistor T3. On this basis, there is no need to additionally provide the control electrode c3 of the driving transistor T3, which may help to simplify the manufacturing process of the pixel driving circuit Q. Furthermore, the second electrode Cst-2 of the storage capacitor Cst may also serve as the control electrode c3 of the driving transistor T3, so that the second electrode Cst-2 of the storage capacitor Cst may be directly electrically connected to the control electrode c3 of the driving transistor T3 without additionally providing a connecting portion, which may also facilitate the layout of the pixel driving circuit Q.

As shown in FIGS. 7, 13 and 14, the first wiring metal layer SD1 is located on a side of the second gate metal layer Gate2 away from the first gate metal layer Gate1.

For example, a material of the first wiring metal layer SD1 may be a multi-laminated composite material of titanium (Ti)-aluminum (AI)-titanium (Ti).

As an example, a first planarization layer (PLN) is provided between the first wiring metal layer SD1 and the second gate metal layer Gate2. The first planarization layer may electrically insulate the first wiring metal layer SD1 from the second gate metal layer Gate2.

For example, a material of the first planarization layer is generally an organic material. For instance, the material of the first planarization layer may include at least one of polyimide (PI), an acrylic acid-based polymer, or a silicon-based polymer.

In addition, the first wiring metal layer SD1 may be used to form a plurality of second scanning signal lines G2 extending in the row direction X and arranged in the column direction Y and a plurality of third scanning signal lines G3 extending in the row direction X and arranged in the column direction Y. Furthermore, the first wiring metal layer SD1 may be used to form a plurality of conductive portions, and the conductive portions are used to connect transistors or connect transistors and signal lines in the pixel driving circuits Q.

As shown in FIGS. 7, 15 and 16, the second wiring metal layer SD2 is located on a side of the first wiring metal layer SD1 away from the first gate metal layer Gate1.

In some examples, a material of the second wiring metal layer SD2 may be the same as the material of the first wiring metal layer SD1. It will be understood that the material of the second wiring metal layer SD2 may be different from the material of the first wiring metal layer SD1, which is not limited in the embodiments of the present disclosure.

For example, a second planarization layer is provided between the second wiring metal layer SD2 and the first wiring metal layer SD1. The second planarization layer electrically insulates the second wiring metal layer SD2 from the first wiring metal layer SD1.

As an example, a material of the second planarization layer is generally an organic material. For example, the material of the second planarization layer may include at least one of polyimide (PI), an acrylic acid-based polymer, or a silicon-based polymer.

In addition, the second wiring metal layer SD2 may also be used to form a plurality of first power signal lines VDD arranged in the row direction X and extending in the column direction Y. The first power signal line VDD is configured to transmit a constant voltage signal to provide a first power signal to the pixel driving circuit Q.

As shown in FIGS. 7, 17 and 18, the light-emitting device layer 210 includes an anode layer 211, and the anode layer 211 is located on a side of the second wiring metal layer SD2 away from the first wiring metal layer SD1. The anode layer 211 includes a plurality of anodes W. The plurality of anodes include a first anode W1, a second anode W2, and a third anode W3. The first anode W1 may be electrically connected to a pixel driving circuit Q in an (m+1)-th column, the second anode W2 may be electrically connected to an m-th column of pixel driving circuits Q, and the third anode W3 may be electrically connected to a pixel driving circuit Q in an (m+2)-th column.

The first anode W1, the second anode W2 and the third anode W3 in the anode layer 211 are anodes of light-emitting devices O in different sub-pixel regions PO. Based on this, it is possible to use the plurality of pixel driving circuits Q in the display substrate 100 to drive the light-emitting devices O electrically connected to the plurality of pixel driving circuits Q to make the display substrate 100 display images.

As shown in FIGS. 6 to 17, a plurality of data signal line groups D are included in the display substrate 100, and a data signal line group D is electrically connected to a column of pixel driving circuits Q. A data signal line group D includes n data signal lines Data extending in the column direction Y and arranged at intervals in the row direction X. Correspondingly, a column of pixel driving circuits Q may be divided into n pixel driving circuit groups E, where n is a positive integer greater than or equal to 2.

Based on this, different data signal lines Data in a same data signal line group D may arranged to be electrically connected to different pixel driving circuit groups E in a same column of pixel driving circuits Q, and a data signal line Data is electrically connected to all pixel driving circuits Q in a pixel driving circuit group E, which is equivalent to that the pixel driving circuits Q in a same column are driven by multiple data signal lines Data in a same data signal line group D, i.e., a data signal line Data is used to drive some pixel driving circuits Q in a column of pixel driving circuits Q.

With this arrangement, the way in which a column of pixel driving circuits Q is driven by a data signal line group D may reduce the number of pixel driving circuits Q (number of rows) driven by each data signal line Data in comparison with the above-mentioned way in which a same column of pixel driving circuits Q is driven by one data signal line Data. Thus, the refresh duration of the pixel driving circuit Q may be increased, which means that the time of threshold compensation for the pixel driving circuit Q may be increased, so that the effect of threshold compensation for the pixel driving circuit Q may be improved, and the display uniformity of the display substrate 100 may be improved. Therefore, the display substrate 100 provided in the embodiments of the present disclosure may be applied to a display device 200 with a high resolution and a high refresh rate, which improves user's experience. Moreover, the display substrate 100 provided in the embodiments of the present disclosure is also applicable to a display device 200 with a low refresh rate, which is conducive to reducing power consumption.

In some embodiments, as shown in FIGS. 6 to 17, the data signal lines Data in the plurality of data signal line groups D may be located in the second wiring metal layer SD2, and the embodiments of the present disclosure are not limited thereto. For example, in a case where the driving circuit layer 20 of the display substrate 100 further includes a third wiring metal layer SD3, the data signal lines Data in the plurality of data signal line groups D may be located in the second wiring metal layer SD2 and/or the third wiring metal layer SD3, and for this structure, detailed description will be made below.

Firstly, the description is made with an example in which the data signal lines Data in the plurality of data signal line groups D are located in the second wiring metal layer SD2.

In some examples, the description will be made by taking n=2 as an example: a data signal line group D includes 2 data signal lines Data extending in the column direction Y and arranged at intervals in the row direction X, and a column of pixel driving circuits Q are divided into 2 pixel driving circuit groups E. FIG. 6 shows 2 rows of pixel driving circuits, then the two adjacent pixel driving circuits Q in the column direction Y in FIG. 6 are pixel driving circuits Q in different pixel driving circuit groups E, respectively.

The 2 data signal lines Data in a data signal line group D may be a first data signal line Data and a second data signal line Data. The 2 pixel driving circuit groups E in the column of pixel driving circuits Q may be a first pixel driving circuit group E and a second pixel driving circuit group E.

With this arrangement, the first data signal line Data may be arranged to be electrically connected to all the pixel driving circuits Q in the first pixel driving circuit group E, and the second data signal line Data may be arranged to be electrically connected to all the pixel driving circuits Q in the second pixel driving circuit group E. Based on this, both the first data signal line Data and the second data signal line Data are used to drive one pixel driving circuit group E. That is, 1 data signal line Data is used to drive some pixel driving circuits Q in a column of pixel driving circuits Q. Thus, it is conducive to increasing the refresh duration of the pixel driving circuit Q, which may increase the time of threshold compensation for the pixel driving circuit Q, so that the effect of threshold compensation for the pixel driving circuit Q may be improved to improve the display uniformity of the display substrate 100. F is the refresh rate of the display substrate 100, and H is the number of rows of the pixel driving circuits Q in the display substrate 100.

In some embodiments, as shown in FIGS. 6 and 7, in a same column of pixel driving circuits Q, the number of pixel driving circuits Q in each pixel driving circuit group E is substantially the same, which is equivalent to that all the pixel driving circuits Q in a same column of pixel driving circuits Q are equally divided into multiple pixel driving circuit groups E, so that the number of pixel driving circuits Q that are driven by different data signal lines Data in a same data signal line group D may be the same.

It will be noted that, due to the existence of certain uncontrollable errors (e.g., multiple pixel driving circuits Q in a same column of pixel driving circuits Q cannot be equally divided), in a same column of pixel driving circuits Q, the case that the difference in the number of pixel driving circuits Q in two pixel driving circuit groups E fluctuates within 5% of the number of pixel driving circuits Q in one of the pixel driving circuit groups E may also be considered as that the numbers of pixel driving circuits Q in the two pixel driving circuit groups E are equal.

On this basis, in a same column of pixel driving circuits Q, the refresh durations of the pixel driving circuits Q in different pixel driving circuit groups E may all be approximately n/FH. In this way, not only the refresh duration of the pixel driving circuit Q may be n times of the above refresh duration

$$\frac{1}{FH} ,$$

but also the refresh durations of the pixel driving circuits Q in different pixel driving circuit groups E in a same column of pixel driving circuits Q may be the same, which is conducive to improving the display uniformity of the display substrate 100.

It will be noted that, due to the existence of certain uncontrollable errors (e.g., manufacturing errors, equipment precision, or measurement errors), the case that the error of the refresh duration of the pixel driving circuit Q fluctuates within

$$5 \% \times \frac{n}{FH}$$

may also be considered as that the refresh duration of the pixel driving circuit Q satisfies being equal to n/FH.

In some examples, the description will be made by taking n=2 as an example: 2 data signal lines Data in a data signal line group D may be a first data signal line Data and a second data signal line Data. 2 pixel driving circuit groups E in a column of pixel driving circuits Q may be a first pixel driving circuit group E and a second pixel driving circuit group E.

The number of pixel driving circuits Q in the first pixel driving circuit group E is substantially equal to the number of pixel driving circuits Q in the second pixel driving circuit group E, which is equivalent to that a column of pixel driving circuits Q are equally divided into 2 parts. On this basis, the refresh duration of the pixel driving circuit Q is approximately

$$\frac{2}{FH} ;$$

that is, the refresh duration of the pixel driving circuit Q is 2 times of the above-mentioned refresh duration

$$\frac{1}{FH} ,$$

where the refresh duration of the pixel driving circuit Q is doubled, which may improve the effect of threshold compensation for the pixel driving circuit Q. In addition, in a same column of pixel driving circuits Q, the refresh duration of any pixel driving circuit Q in the first pixel driving circuit group E may be made substantially equal to the refresh duration of any pixel driving circuit Q in the second pixel driving circuit group E, which is conducive to improving the display uniformity of the display substrate 100.

In some embodiments, in a same column of pixel driving circuits Q, multiple pixel driving circuit groups E are sequentially arranged in the column direction Y. The pixel driving circuits Q in each pixel driving circuit group E are centrally arranged to facilitate the subsequent electrical connections between the pixel driving circuits Q and corresponding data signal lines Data, which may simplify the layout of the display substrate 100.

For example, in a case where a column of pixel driving circuits Q includes 4 pixel driving circuit groups E, the 4 pixel driving circuit groups E are a first pixel driving circuit group E, a second pixel driving circuit group E, a third pixel driving circuit group E and a fourth pixel driving circuit group E. In this case, in the column direction, the first pixel driving circuit group E, the second pixel driving circuit group E, the third pixel driving circuit group E and the fourth pixel driving circuit group E are arranged in sequence.

In another embodiment, in a same column of pixel driving circuits Q, the pixel driving circuits Q in the multiple pixel driving circuit groups E are alternately arranged in the column direction Y. The pixel driving circuits Q in each pixel driving circuit group E are dispersedly arranged, which may improve the flexibility and applicability of the layout of the pixel driving circuits Q in the display substrate 100.

In some embodiments, as shown in FIG. 7, two adjacent columns of pixel driving circuits Q are the m-th column of pixel driving circuits Q and the (m+1)-th column of pixel driving circuits Q. The data signal line group D electrically connected to the m-th column of pixel driving circuits Q includes at least one first data signal line Data1-1, and the first data signal line Data1-1 is located between the m-th column of pixel driving circuits Q and the (m+1)-th column of pixel driving circuits Q. The data signal line group D electrically connected to the (m+1)-th column of pixel driving circuits Q includes at least one second data signal line Data2-1, and the second data signal line Data2-1 is located between the m-th column of pixel driving circuits Q and the (m+1)-th column of pixel driving circuits Q, where m is a positive integer.

The first data signal line Data1-1 electrically connected to the m-th column of pixel driving circuits Q and the second data signal line Data2-1 electrically connected to the (m+1)-th column of pixel driving circuits Q are arranged adjacent to each other and are both disposed between the m-th column of pixel driving circuits Q and the (m+1)-th column of pixel driving circuits Q, whereby an overlapping area of orthographic projections of the data signal lines Data on the substrate 10 and orthographic projections of the pixel driving circuits Q on the substrate 10 may be reduced to prevent the data signal lines Data from affecting the stability of the pixel driving circuits Q, which is conducive to improving the display uniformity of the display substrate 100.

In some examples, multiple data signal lines Data in a data signal line group D are all located on a side of a column of pixel driving circuits Q electrically connected to the data signal line group D.

All the data signal lines Data in the data signal line group D electrically connected to the m-th column of pixel driving circuits Q are first data signal lines Data1-1. That is, all the data signal lines Data (the first data signal lines Data1-1) in the data signal line group D electrically connected to the m-th column of pixel driving circuits Q are located between the m-th column of pixel driving circuits Q and the (m+1)-th column of pixel driving circuits Q. All the data signal lines Data in a data signal line group D are centrally arranged, which may simplify the layout of the data signal lines Data in the display substrate 100.

All the data signal lines Data in the data signal line group D electrically connected to the (m+1)-th column of pixel driving circuits Q are second data signal lines Data2-1. That is, all the data signal lines Data (the second data signal lines Data2-1) in the data signal line group D electrically connected to the (m+1)-th column of pixel driving circuits Q are located between the m-th column of pixel driving circuits Q and the (m+1)-th column of pixel driving circuits Q. All the data signal lines Data in a data signal line group D are centrally arranged, which may simplify the layout of the data signal lines Data in the display substrate 100.

In some other examples, as shown in FIG. 7, multiple data signal lines Data in a data signal line group D are divided into a first part of data signal lines Data-1 and a second part of data signal lines Data-2, and the first part of data signal lines Data-1 and the second part of data signal lines Data-2 are respectively located on two sides of a column of pixel driving circuits Q electrically connected to the data signal line group D.

With such an arrangement in which the first part of data signal lines Data-1 and the second part of data signal lines Data-2 in the data signal line group D are respectively disposed on two sides of the pixel driving circuits Q, the spacing between the first part of data signal lines Data-1 and the second part of data signal lines Data-2 in the data signal line group D may be increased to alleviate the problem of crosstalk between multiple data signal lines Data, which is conducive to improving the display uniformity of the display substrate 100.

The multiple data signal lines Data in the data signal line group D electrically connected to the m-th column of pixel driving circuits Q are divided into two parts. The first part of data signal lines Data-1 is a first data signal line Data1-1 located between the m-th column of pixel driving circuits Q and the (m+1)-th column of pixel driving circuits Q. The second part of data signal lines Data-2 is a third data signal line Data1-2 located on a side of the m-th column of pixel driving circuits Q away from the (m+1)-th column of pixel driving circuits Q. In a case where m is a positive integer greater than or equal to 4, the third data signal line Data1-2 is located between the m-th column of pixel driving circuits Q and an (m−1)-th column of pixel driving circuits Q.

With such an arrangement in which the first part of data signal lines Data-1 (the first data signal line Data1-1) and the second part of data signal lines Data-2 (the third data signal line Data1-2) in the data signal line group D may be respectively arranged on two sides of the pixel driving circuit Q, the spacing between the first part of data signal lines Data-1 (the first data signal line Data1-1) and the second part of data signal lines Data-2 (the third data signal line Data1-2) in the data signal line group D may be increased to alleviate the problem of crosstalk between multiple data signal lines Data, which is conducive to improving the display uniformity of the display substrate 100.

The multiple data signal lines Data in the data signal line group D electrically connected to the (m+1)-th column of pixel driving circuits Q are divided into two parts. The first part of data signal lines Data-1 is a second data signal line Data2-1, which is located between the m-th column of pixel driving circuits Q and the (m+1)-th column of pixel driving circuits Q. The second part of data signal lines Data-2 is a fourth data signal line Data2-2, which is located between the (m+1)-th column of pixel driving circuits Q and an (m+2)-th column of pixel driving circuits Q.

With such an arrangement in which the first part of data signal lines Data-1 (the second data signal line Data2-1) and the second part of data signal lines Data-2 (the fourth data signal line Data2-2) in the data signal line group D may be respectively arranged on two sides of the pixel driving circuit Q, the spacing between the first part of data signal lines Data-1 (the second data signal line Data2-1) and the second part of data signal lines Data-2 (the fourth data signal line Data2-2) in the data signal line group D may be increased to alleviate the problem of crosstalk between multiple data signal lines Data, which is conducive to improving the display uniformity of the display substrate 100.

It will be noted that, as shown in FIG. 7, the difference between the pixel driving circuits Q in the upper row and the lower row is that they are pixel driving circuits Q belong to different pixel driving circuit groups E, and they are correspondingly connected to different data signal lines Data in a same data signal line group D. Description is made below by taking the (m+1)-th column of pixel driving circuits and data signal lines Data electrically connected thereto as an example. In this case, as shown in FIG. 7, a pixel driving circuit Q in the first row and second column is a pixel driving circuit of the (m+1)-th column of pixel driving circuits, and a pixel driving circuit Q in the second row and second column is another pixel driving circuit of the (m+1)-th column of pixel driving circuits. For the 2 data signal lines Data electrically connected to the above two pixel driving circuits Q of the (m+1)-th column of pixel driving circuits, the second data signal line Data2-1 is electrically connected to the pixel driving circuit Q in the second row and second column, and the fourth data signal line Data2-2 is electrically connected to the pixel driving circuit Q in the first row and the second column.

Since the 2 data signal lines Data electrically connected to the (m+1)-th column of pixel driving circuits are located on two sides of the (m+1)-th column of pixel driving circuits, the distance between one of the 2 data signal lines Data and a data writing transistor T4 of a respective pixel driving circuit Q is different from the distance between the other data signal line Data and a data writing transistor T4 of a respective pixel driving circuit Q. Thus, it may be possible to cause a structure of a transfer portion between the data writing transistor T4 of the pixel driving circuit Q in the upper row and the data signal line Data electrically connected to the pixel driving circuit Q in the upper row to be different from that between the data writing transistor T4 of the pixel driving circuit Q in the lower row and the data signal line Data electrically connected to the pixel driving circuit Q in the lower row. For the structure of the transfer portion between the data writing transistor T4 and the data signal line Data electrically connected thereto, detailed description will be made below.

In some examples, the number of data signal lines Data in the first part of data signal lines Data-1 is approximately equal to the number of data signal lines Data in the second part of data signal lines Data-2.

In the first part of data signal lines Data-1 and the second part of data signal lines Data-2 that are respectively disposed on two sides of a column of pixel driving circuits Q, the number of data signal lines Data may be approximately the same, so that the problem of short circuit caused by the case that too many data signal lines Data are on a side of the column of pixel driving circuits Q may be avoided, which is conducive to improving the quality of the display substrate 100.

It will be noted that, due to the existence of certain uncontrollable errors (e.g., multiple data signal lines Data in a same data signal line group D cannot be equally divided), in a same data signal line group D, the difference between the number of data signal lines Data in the first part of data signal lines Data-1 and the number of data signal lines Data in the second part of data signal lines Data-2 fluctuates within 5% of the number of data signal lines Data in the first part of data signal lines Data-1 or the number of data signal lines Data in the second part of data signal lines Data-2, which may also be considered as that the number of data signal lines Data in the first part of data signal lines Data-1 and the number of data signal lines Data in the second part of data signal lines Data-2 are equal.

However, the inventors have found through researches that, the number of data signal lines Data in the display substrate 100 is increased to alleviate the problem of insufficient threshold compensation for the pixel driving circuit Q. Thus, it will cause multiple data signal lines Data electrically connected to two adjacent columns of pixel driving circuits Q to be closely arranged with a small distance between each other, resulting in a large parasitic capacitance formed between adjacent data signal lines Data, which may lead to a serious problem of lateral crosstalk between adjacent data signal lines Data, so that the display effect of the display substrate 100 is reduced.

For example, when the display substrate 100 is in operation, since different data signal lines Data driving different columns of pixel driving circuits Q transmit different data writing signals, the data writing signal transmitted by any data signal line Data will affect an adjacent data signal line Data, which results in a problem of crosstalk between adjacent data signal lines Data and affects the display uniformity of the display substrate 100. That is, the problem of crosstalk will easily occur between the first data signal line Data1-1 and the second data signal line Data2-1.

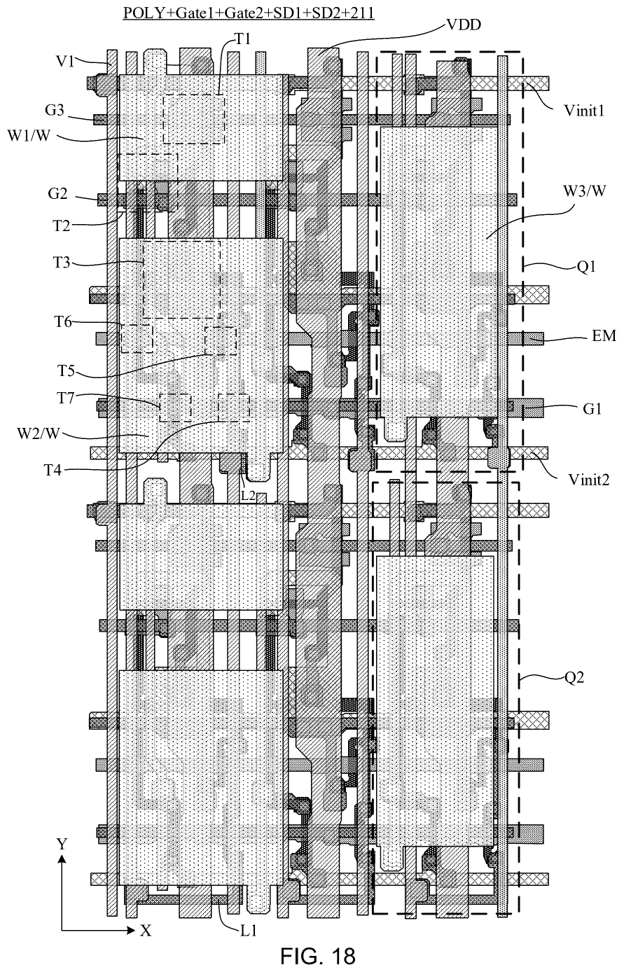

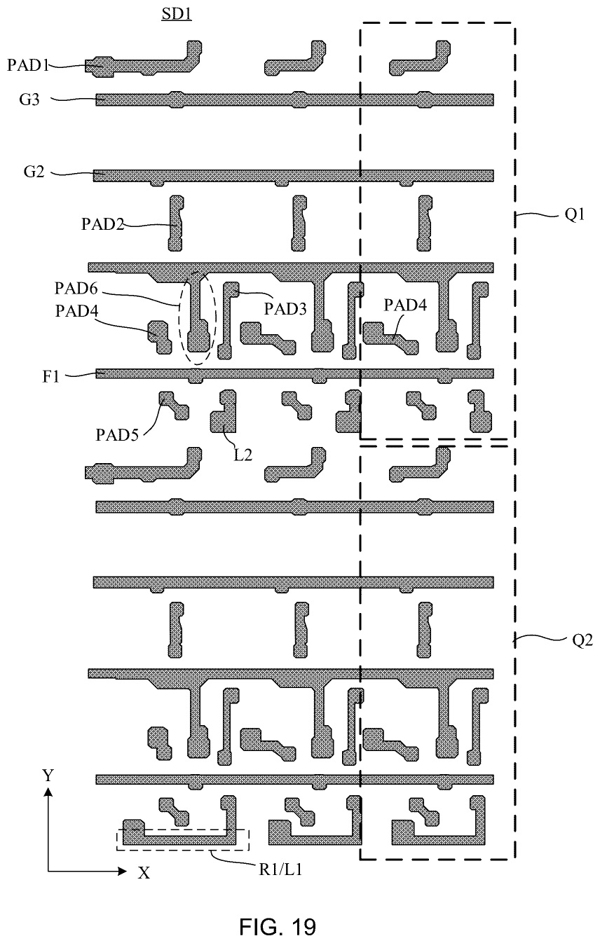

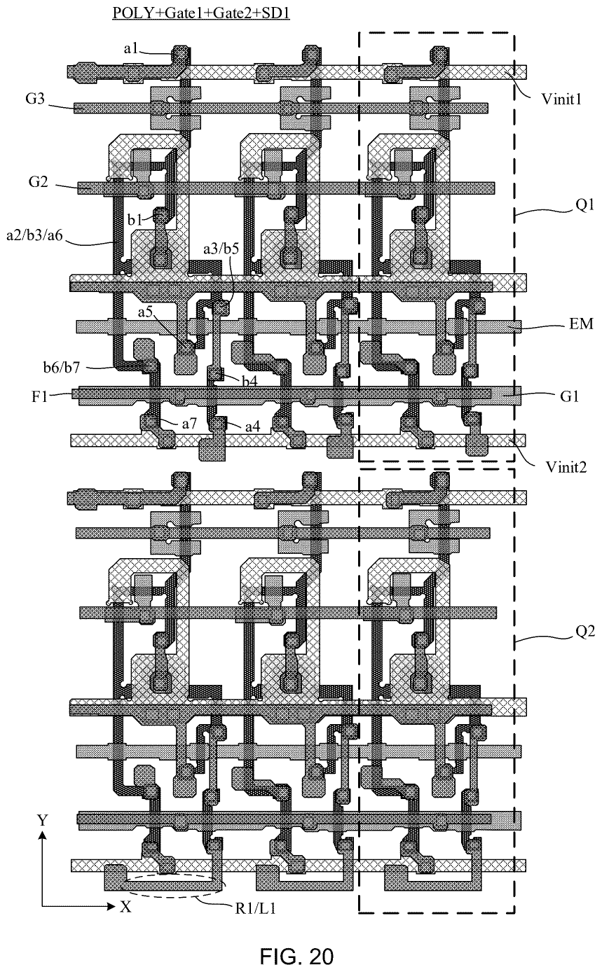

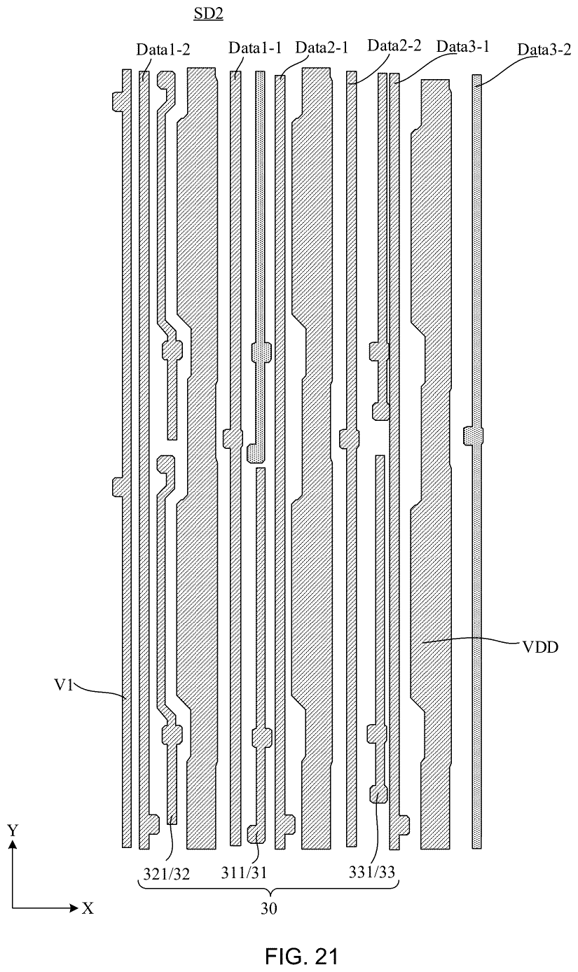

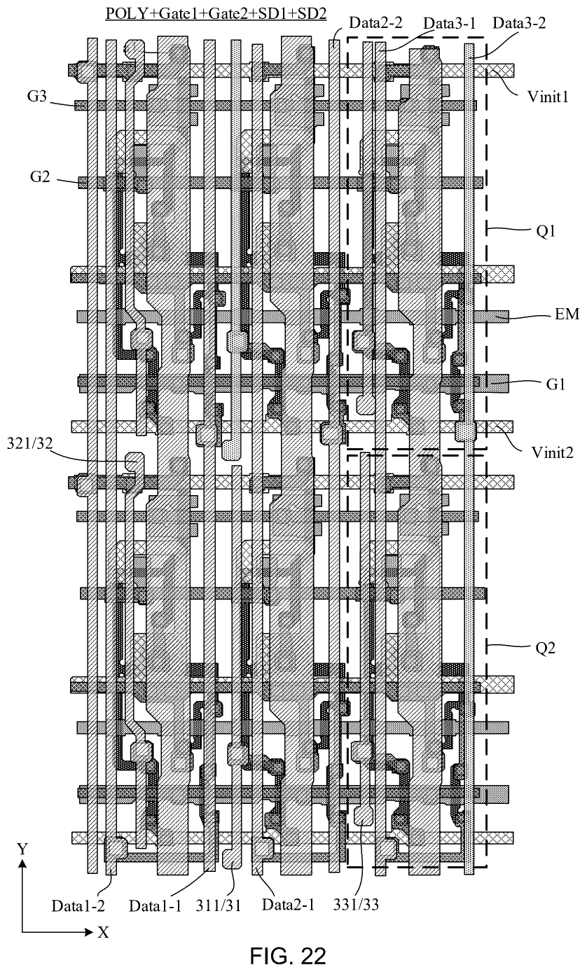

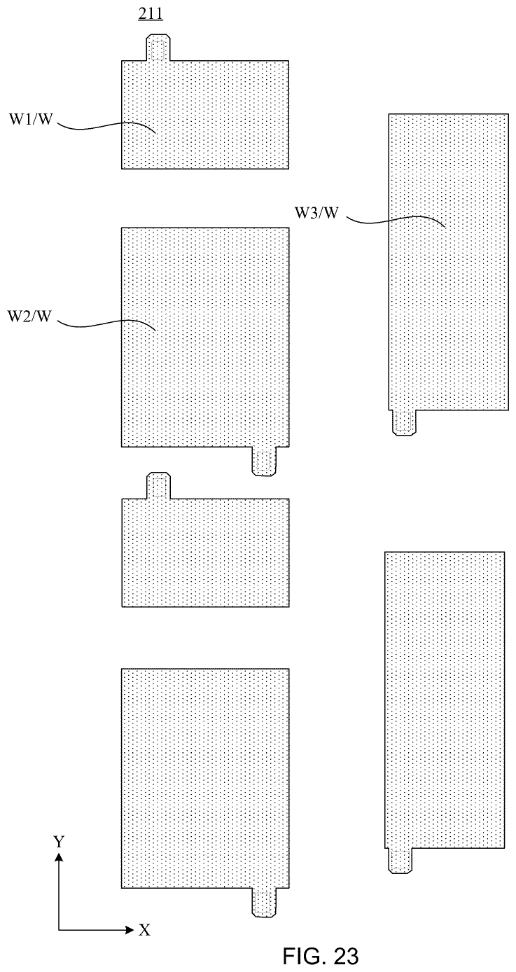

FIG. 18 is a diagram showing a connection between a pixel driving circuit and a light-emitting layer, in accordance with some other embodiments. FIG. 19 is a film layer structural diagram of a first wiring metal layer in FIG. 18; FIG. 20 is a film layer structural diagram of a first semiconductor layer, a first gate metal layer, a second gate metal layer, and a first wiring metal layer in FIG. 18; FIG. 21 is a film layer structural diagram of a second wiring metal layer in FIG. 18; FIG. 22 is a film layer structural diagram of a first semiconductor layer, a first gate metal layer, a second gate metal layer, a first wiring metal layer, and a second wiring metal layer in FIG. 18; FIG. 23 is a film layer structural diagram of an anode layer in FIG. 18.

In order to clearly illustrate the structure of each pixel driving circuit, FIG. 18 schematically illustrates pixel driving circuits Q of 2 rows and 3 columns rather than all rows of pixel driving circuits Q in the display substrate 100. That is, FIG. 18 shows 6 pixel driving circuits and the data signal lines Data electrically connected thereto.

On this basis, referring to FIGS. 18 to 23, the driving circuit layer 20 of the display substrate 100 provided in some embodiments of the present disclosure further includes a plurality of anode transfer lines 30, and the plurality of anode transfer lines 30 are respectively electrically connected to driving output terminals (the fourth nodes N4) of the plurality of pixel driving circuits Q. Multiple anode transfer lines 30 electrically connected to the (m+1)-th column of pixel driving circuits Q include at least one first anode transfer line 31. The first anode transfer line 31 includes a first anode transfer portion 311, the first anode transfer portion 311 is configured to have a constant voltage potential, and the first anode transfer portion 311 is disposed in the same layer as the data signal line Data.

The first anode transfer portion 311 is used to electrically connect an anode of a light-emitting device O and an output end of a pixel driving circuit Q, so that the anode of the light-emitting device O is electrically connected to the output end of the pixel driving circuit Q. In this way, in the light-emitting phase, the pixel driving circuit Q may transmit a first power signal received from the first power signal line VDD to the driving output terminal (the fourth node N4), and then transmit the first power signal to the anode of the light-emitting device O through the first anode transfer portion 311, so as to create a voltage difference between the first power signal and a second power signal provided by the second power signal line connected to the cathode of the light-emitting device O to drive the light-emitting device O to emit light. That is, the first anode transfer portion 311 is configured to have a constant voltage potential.

The first anode transfer portion 311 is disposed in the same layer as the data signal line Data, so that there is small number of film layers sandwiched between the first anode transfer portion 311 and the anode layer 211, which facilitates the electrical connection between the first anode transfer portion 311 and the anode in the anode layer 211. In addition, the first anode transfer portion 311 and the data signal line Data are disposed in the same layer, so that the first anode transfer portion 311 and the data signal line Data may be formed in a single patterning process, which may be conducive to simplifying the manufacturing processes to improve the yield. However, the embodiments of the present disclosure are not limited to the above, and the first anode transfer portion 311 and the data signal line Data may be formed separately in two manufacturing processes.

It will be noted that, the term “same layer” refers to a layer structure formed through a single patterning process by using a same mask in which a film layer for forming a specific pattern is formed by using a same film-forming process. Depending on different specific patterns, the single patterning process may include multiple times of exposure, development or etching, and the specific pattern formed in the layer structure may be continuous or discontinuous, and these specific patterns may also be at different heights or have different thicknesses.

On this basis, in the row direction X, the first anode transfer portion 311 is disposed between the first data signal line Data1-1 electrically connected to the m-th column of pixel driving circuits Q and the second data signal line Data2-1 electrically connected to the (m+1)-th column of pixel driving circuits Q.

On the basis that the first anode transfer portion 311 and the data signal line Data are disposed in the same layer, in the case where the first anode transfer portion 311 is disposed between the first data signal line Data1-1 and the second data signal line Data2-1, a space needs to be reserved between the first data signal line Data1-1 and the second data signal line Data2-1 to arrange the first anode transfer portion 311. Thus, it helps to increase the spacing between the first data signal line Data1-1 and the second data signal line Data2-1 and reduce the parasitic capacitance generated between the first data signal line Data1-1 and the second data signal line Data2-1. As a result, the problem that the potential of the data signal line Data jumps when an adjacent data signal line Data transmits a data writing signal may be alleviated, thereby alleviating the problem of lateral crosstalk in the display substrate 100.

Furthermore, the first anode transfer portion 311 is configured to have a constant voltage potential. Thus, in the case where the first anode transfer portion 311 is disposed between the first data signal line Data1-1 and the second data signal line Data2-1, the first anode transfer portion 311 may be used to isolate the first data signal line Data1-1 from the second data signal line Data2-1, so as to further reduce the parasitic capacitance generated between the first data signal line Data1-1 and the second data signal line Data2-1 to alleviate the problem of crosstalk between the first data signal line Data1-1 and the second data signal line Data2-1, thereby improving the display uniformity of the display substrate 100, so as to improve the display effect of the display substrate 100.

To summarize, in the display substrate 100 provided in some embodiments of the present disclosure, the number of data signal lines Data is increased to make a data signal line group D (multiple data signal lines Data) drive a column of pixel driving circuits Q, which increases the refresh duration of the pixel driving circuit Q, increases the charging time of the pixel driving circuit Q, so that the effect of threshold compensation for the pixel driving circuit Q is improved, so as to improve the display uniformity of the display substrate 100. Moreover, the display substrate 100 is further provided with first anode transfer portions 311 disposed in the same layer as the data signal lines Data, and the first anode transfer portion 311 is used to separate the first data signal line Data1-1 from the second data signal line Data2-1, which alleviates the problem of crosstalk between the first data signal line Data1-1 and the second data signal line Data2-1, and further ensures the display effect of the display substrate 100.

In some embodiments, as shown in FIGS. 18 and 23, the light-emitting device layer 210 of the display substrate 100 further includes an anode layer 211, and the anode layer 211 is located on a side of the driving circuit layer 20 away from the substrate 10. The anode layer 211 includes a plurality of anodes W, the plurality of anodes W include first anodes W1, second anodes W2 and third anodes W3; in the column direction Y, the first anodes W1 and the second anodes W2 are alternately arranged, and in the row direction X, a third anode W3 overlaps with a first anode W1, and the third anode W3 overlaps with a second anode W2.

The first anode W1 and the second anode W2 in the anode layer 211 are anodes of light-emitting devices O in different sub-pixel regions PO. Based on this, the plurality of pixel driving circuits Q in the display substrate 100 are used to drive the light-emitting devices O electrically connected thereto, so that the display substrate 100 displays images.

For example, the first anode W1 may be an anode of a light-emitting device O in a red sub-pixel, the second anode W2 may be an anode of a light-emitting device O in a green sub-pixel, and the third anode W3 may be an anode of a light-emitting device O in a blue sub-pixel, and the embodiments of the present disclosure are not limited thereto.

Since the first anode transfer portion 311 and the data signal line Data are in the same layer, the first anode transfer portion 311 is arranged to extend in the column direction Y. That is, the extension direction of the first anode transfer portion 311 is substantially the same as the extension direction of the data signal line Data, which may prevent the first anode transfer portion 311 and the data signal line Data from being short-circuited.

The (m+1)-th column of pixel driving circuits Q may be electrically connected to second anodes W2 through first anode transfer portions 311, and an orthographic projection of a first anode transfer portion 311 on the substrate 10 is arranged to overlap with an orthographic projection of a second anode W2 on the substrate 10. Thus, a portion of the first anode transfer portion 311 and a portion of the second anode W2 whose orthographic projections on the substrate 10 overlap with each other, may be connected through a via hole to achieve the electrical connection between the first anode transfer portion 311 and the second anode W2. Moreover, there is no need to additionally provide a connecting portion to electrically connect the first anode transfer portion 311 to the second anode W2, which may help to save the limited space in the display substrate 100 and facilitate the layout of the display substrate 100.

The inventors have found through researches that, in the case where the orthographic projection of the first anode transfer portion 311 on the substrate 10 overlaps with the orthographic projection of the second anode W2 on the substrate 10, since the first anode transfer portion 311 does not need to be electrically connected to other anodes, the orthographic projection of the first anode transfer portion 311 on the substrate 10 is generally arranged to be non-overlapping with an orthographic projection of a first anode W1 on the substrate 10. Furthermore, the first anodes W1 and the second anodes W2 are alternately arranged in the column direction Y, and the second wiring metal layer SD2 under the first anodes W1 and second anodes W2 has substantially the same layout at the positions corresponding to the first anodes W1 and the second anodes W2, the difference of which lies in positions corresponding to the positions where the first anodes W1 and the second anodes W2 are connected to the respective anode transfer portions. That is, since a position of the second wiring metal layer SD2 corresponding to a first anode W1 is provided with no first anode transfer portion 311, this position is a blank space, and the blank space will be filled with a planarization layer between the second wiring metal layer SD2 and the anode layer 211. However, due to a level difference between the blank space and the second wiring metal layer SD2, a level difference will appear on a surface of the planarization layer between the second wiring metal layer SD2 and the first anode W1 away from the substrate, which increases the difficulty of forming the anode layer 211 (the first anode W1) on the planarization layer, and affects the quality of the light-emitting device O.

Based on this, in the display substrate 100 provided in some embodiments of the present disclosure, the first anode transfer portion 311 extends to a position corresponding to the first anode W1 such that the orthographic projection of the first anode transfer portion 311 on the substrate 10 overlaps with the orthographic projection of the first anode W1 on the substrate 10.

With such an arrangement, the blank space mentioned above may be filled with the first anode transfer portion 311 to alleviate the problem of uneven surface of the planarization layer between the second wiring metal layer SD2 and the anode layer 211 away from the substrate, which is conducive to improving the quality of the anode layer 211 formed on the surface of the planarization layer away from the substrate.

In some embodiments, as shown in FIGS. 18 and 22, in the column direction Y, orthographic projections of a first anode W1 and a second anode W2 on the substrate 10 are located between orthographic projections of two ends of a first anode transfer portion 311 on the substrate 10. Based on this, the positional relationship between the first anode transfer portion 311 and the first anode W1 and second anode W2 includes the following situations, where the two ends of the first anode transfer portion 311 include a first end near the first anode W1 and a second end near the second anode W2.

The first situation: an orthographic projection of a portion of the first end of the first anode transfer portion 311 away from the second end of the first anode transfer portion 311 on the substrate 10 substantially coincides with an orthographic projection of a portion of the first anode W1 away from the second anode W2 on the substrate 10; in addition, an orthographic projection of a portion of the second end of the first anode transfer portion 311 away from the first end of the first anode transfer portion 311 on the substrate 10 substantially coincides with an orthographic projection of a portion of the second anode W2 away from the first anode W1 on the substrate 10. That is, the portion of the first end of the first anode transfer portion 311 away from the second end of the first anode transfer portion 311 is substantially aligned with the portion of the first anode W1 away from the second anode W2, and the portion of the second end of the first anode transfer portion 311 away from the first end of the first anode transfer portion 311 is substantially aligned with the portion of the second anode W2 away from the first anode W1.

With this design, the first anode transfer portion 311 is extended to alleviate the problem of uneven surface of the planarization layer at positions corresponding the first anode W1 and the second anode W2, which is conducive to improving the quality of the anode layer 211.

It will be noted that, the term “substantially coincide with” includes absolute coincidence and approximate coincidence. That is, a spacing between the orthographic projection of the portion of the first end of the first anode transfer portion 311 away from the second end of the first anode transfer portion 311 on the substrate 10 and the orthographic projection of the portion of the first anode W1 away from the second anode W2 on the substrate 10 fluctuates without exceeding an error threshold. Alternatively, it is considered that the orthographic projection of the portion of the first end of the first anode transfer portion 311 away from the second end of the first anode transfer portion 311 on the substrate 10 relatively “coincides” with the orthographic projection of the portion of the first anode W1 away from the second anode W2 on the substrate 10. The error threshold may be less than or equal to 5% of the length of the first anode W1 in the column direction Y.

Similarly, a spacing between the orthographic projection of the portion of the second end of the first anode transfer portion 311 away from the first end of the first anode transfer portion 311 on the substrate 10 and the orthographic projection of the portion of the second anode W2 away from the first anode W1 on the substrate 10 fluctuates without exceeding an error threshold; alternatively, it is considered that the orthographic projection of the portion of the second end of the first anode transfer portion 311 away from the first end of the first anode transfer portion 311 on the substrate 10 relatively “coincides” with the orthographic projection of the portion of the second anode W2 away from the first anode W1 on the substrate 10. The error threshold may be less than or equal to 5% of the length of the second anode W2 in the column direction Y.

The second situation: an orthographic projection of the first end of the first anode transfer portion 311 on the substrate 10 is located outside of the orthographic projection of the first anode W1 on the substrate 10; in addition, an orthographic projection of the second end of the first anode transfer portion 311 on the substrate 10 is located outside of the orthographic projection of the second anode W2 on the substrate 10. That is, the first end of the first anode transfer portion 311 extends to the outside of the first anode W1, and the second end of the first anode transfer portion 311 extends to the outside of the second anode W2.

With this design, the first anode transfer portion 311 is extended and extended to the outside of the corresponding anode as far as the space in the display substrate 100 allows. That is, the flatness of the planarization layer at positions corresponding to the first anode W1 and the second anode W2 may be further ensured, which is conducive to improving the quality of the anode layer 211.

The third situation: the orthographic projection of the portion of the first end of the first anode transfer portion 311 away from the second end of the first anode transfer portion 311 on the substrate 10 substantially coincides with the orthographic projection of the portion of the first anode W1 away from the second anode W2 on the substrate 10; in addition, the orthographic projection of the second end of the first anode transfer portion 311 on the substrate 10 is located outside of the orthographic projection of the second anode W2 on the substrate 10.

With this design, the first anode transfer portion 311 is extended to the outside of the corresponding anode as far as the space in the display substrate 100 allows, so that the flatness of the planarization layer at positions corresponding to the first anode W1 and the second anode W2 may be further ensured, which is conducive to improving the quality of the anode layer 211.

The fourth situation: the orthographic projection of the first end of the first anode transfer portion 311 on the substrate 10 is located outside of the orthographic projection of the first anode W1 on the substrate 10; in addition, the orthographic projection of the portion of the second end of the first anode transfer portion 311 away from the first end of the first anode transfer portion 311 on the substrate 10 substantially coincides with the orthographic projection of the portion of the second anode W2 away from the first anode W1 on the substrate 10.

With this design, the first anode transfer portion 311 is extended to the outside of the corresponding anode as far as the space in the display substrate 100 allows, so that the flatness of the planarization layer at positions corresponding to the first anode W1 and the second anode W2 may be further ensured, which is conducive to improving the quality of the anode layer 211.

In some embodiments, as shown in FIGS. 18 to 23, the data signal line group D electrically connected to the m-th column of pixel driving circuits Q includes at least one third data signal line Data1-2, and the third data signal line Data1-2 is located on a side of the m-th column of pixel driving circuits Q away from the (m+1)-th column of pixel driving circuits Q, where m is a positive integer.

The above structure is equivalent to a case that the multiple data signal lines Data in the data signal line group D electrically connected to the m-th column of pixel driving circuits Q are divided into two parts; the first part of data signal lines Data is the first data signal line Data1-1, which is located between the m-th column of pixel driving circuits Q and the (m+1)-th column of pixel driving circuits Q; the second part of data signal lines Data is the third data signal line Data1-2, which is located between the m-th column of pixel driving circuits Q and the (m−1)-th column of pixel driving circuits.

With such an arrangement, the multiple data signal lines Data in the data signal line group D may be arranged on two sides of the pixel driving circuit Q, and the spacing between the multiple data signal lines Data of the data signal line group D may be increased to alleviate the problem of crosstalk between the multiple data signal lines Data, which is conducive to improving the display uniformity of the display substrate 100.

In order to alleviate the problem of crosstalk between the third data signal line Data1-2 and other data signal lines, as shown in FIGS. 18 to 23, in the anode layer 211 of the display substrate 100 provided in some embodiments of the present disclosure, multiple anode transfer lines 30 electrically connected to the m-th column of pixel driving circuits Q include at least one second anode transfer line 32, the second anode transfer line 32 includes a second anode transfer portion 321, and the second anode transfer portion 321 is in the same layer as the data signal line Data.

The second anode transfer portion 321 and the data signal line Data are disposed in the same layer, so that there is small number of film layers sandwiched between the second anode transfer portion 321 and the anode layer 211, which may facilitate the electrical connection between the second anode transfer portion 321 and the anode in the anode layer 211. Moreover, the second anode transfer portion 321 and the data signal line Data are disposed in the same layer, so that the second anode transfer portion 321 and the data signal line Data may be formed in a single patterning process, which may be conducive to simplifying the manufacturing processes to improve the yield. However, the embodiments of the present disclosure are not limited to the above, and the second anode transfer portion 321 and the data signal line Data may be formed separately in two manufacturing processes.

It will be noted that, the term “same layer” refers to a layer structure formed through a single patterning process by using a same mask in which a film layer for forming a specific pattern is formed by using a same film-forming process. Depending on different specific patterns, the single patterning process may include multiple times of exposure, development or etching, and the specific pattern formed in the layer structure may be continuous or discontinuous, and these specific patterns may also be at different heights or have different thicknesses.

In the row direction X, the second anode transfer portion 321 is located on a side of the m-th column of pixel driving circuits Q away from the (m+1)-th column of pixel driving circuits Q, so that the second anode transfer portion 321 is used to alleviate the crosstalk between the third data signal line Data1-2 and other data signal lines.

In the case of m=1, as shown in FIGS. 18 to 23, the second anode transfer portion 321 may be located between the m-th column of pixel driving circuits Q and the third data signal line Data1-2. Since the m-th column of pixel driving circuits Q is the 1st column of pixel driving circuits Q, there is no data signal line electrically connected to other columns of pixel driving circuits Q on the side of the 1st column of pixel driving circuits Q away from the 2nd column of pixel driving circuits Q. On this basis, it only needs to consider the crosstalk between the first data signal line Data1-1 and the third data signal line Data1-2 that are electrically connected to the 1st column of pixel driving circuits Q.

On the basis that the second anode transfer portion 321 and the data signal line Data are disposed in the same layer, in the case where the second anode transfer portion 321 is disposed between the m-th column of pixel driving circuits Q and the third data signal line Data1-2, a space needs to be reserved between the m-th column of pixel driving circuits Q and the third data signal line Data1-2 to arrange the second anode transfer portion 321, while the first data signal line Data1-1 electrically connected to the m-th column of pixel driving circuits Q is located on a side of the m-th column of pixel driving circuits Q proximate to the (m+1)-th column of pixel driving circuits Q. Thus, the spacing between the first data signal line Data1-1 and the third data signal line Data1-2 may be increased, which helps to reduce the parasitic capacitance generated between the first data signal line Data1-1 and the third data signal line Data1-2. As a result, the crosstalk between the first data signal line Data1-1 and the third data signal line Data1-2 may be alleviated, which helps to improve the display uniformity of the display substrate 100.

Furthermore, the second anode transfer portion 321 is configured to have a constant voltage potential. Thus, in the case where the second anode transfer portion 321 is disposed between the first data signal line Data1-1 and the third data signal line Data1-2, the second anode transfer portion 321 may be used to isolate the first data signal line Data1-1 from the third data signal line Data1-2, so as to further reduce the parasitic capacitance generated between the first data signal line Data1-1 and the third data signal line Data1-2, so as to alleviate the problem of crosstalk between the first data signal line Data1-1 and the third data signal line Data1-2. The principle of configuring the second anode transfer portion 321 to have a constant voltage potential is the same as the principle of configuring the first anode transfer portion 311 to have a constant voltage potential, which will not be repeated here.

In the case where m is a positive integer greater than or equal to 4, the multiple columns of pixel driving circuits Q further include the (m−1)-th column of pixel driving circuits Q, and the (m−1)-th column of pixel driving circuits Q are located on a side of the m-th column of pixel driving circuits Q away from the (m+1)-th column of pixel driving circuits Q. The data signal line group D electrically connected to the m-th column of pixel driving circuits Q includes at least one third data signal line Data1-2, and the third data signal line Data1-2 is located between the (m−1)-th column of pixel driving circuits Q and the m-th column of pixel driving circuits Q. The data signal line group D electrically connected to the (m−1)-th column of pixel driving circuits Q includes at least one seventh data signal line (not shown in the figures), and the seventh data signal line is located between the (m−1)-th column of pixel driving circuits Q and the m-th column of pixel driving circuits Q.

In some examples, all the data signal lines Data in the data signal line group D electrically connected to the (m−1)-th column of pixel driving circuits Q are seventh data signal lines. That is, all the data signal lines Data (the seventh data signal lines) in the data signal line group D electrically connected to the (m−1)-th column of pixel driving circuits Q are located between the m-th column of pixel driving circuits Q and the (m−1)-th column of pixel driving circuits Q. All the data signal lines Data in the data signal line group D are centrally arranged, which may simplify the layout of the data signal lines Data in the display substrate 100.

In some other examples, a part of data signal lines Data in the data signal line group D electrically connected to the (m−1)-th column of pixel driving circuits Q is the seventh data signal line. That is, another part of data signal lines Data in the data signal line group D electrically connected to the (m−1)-th column of pixel driving circuits Q is an eighth data signal line.

This is equivalent to that the multiple data signal lines Data in the data signal line group D electrically connected to the (m−1)-th column of pixel driving circuits Q are divided into two parts. The first part of data signal lines Data is the seventh data signal line, which is located between the m-th column of pixel driving circuits Q and the (m−1)-th column of pixel driving circuits Q; and the second part of data signal lines Data is the eighth data signal line, which is located on a side of the (m−1)-th column of pixel driving circuits Q away from the m-th column of pixel driving circuits Q.

In the row direction X, the second anode transfer portion 321 may be disposed between the third data signal line Data1-2 electrically connected to the m-th column of pixel driving circuits Q and the seventh data signal line electrically connected to the (m−1)-th column of pixel driving circuits Q.

On the basis that the second anode transfer portion 321 and the data signal line Data are disposed in the same layer, in the case where the second anode transfer portion 321 is disposed between the third data signal line Data1-2 and the seventh data signal line, a space needs to be reserved between the third data signal line Data1-2 and the seventh data signal line to arrange the second anode transfer portion 321. Thus, it helps to increase the spacing between the third data signal line Data1-2 and the seventh data signal line and reduce the parasitic capacitance generated between the third data signal line Data1-2 and the seventh data signal line. As a result, the problem that the potential of the data signal line Data jumps when an adjacent data signal line Data transmits a data write signal may be alleviated, thereby alleviating the problem of lateral crosstalk in the display substrate 100.

Furthermore, the second anode transfer portion 321 is configured to have a constant voltage potential. Thus, in the case where the second anode transfer portion 321 is disposed between the third data signal line Data1-2 and the seventh data signal line, the second anode transfer portion 321 is used to isolate the third data signal line Data1-2 from the seventh data signal line, so as to further reduce the parasitic capacitance generated between the third data signal line Data1-2 and the seventh data signal line, so as to alleviate the problem of crosstalk between the third data signal line Data1-2 and the seventh data signal line. The principle of configuring the second anode transfer portion 321 to have a constant voltage potential is the same as the principle of configuring the first anode transfer portion 311 to have a constant voltage potential, which will not be repeated here.

In some embodiments, as shown in FIGS. 18 to 23, since the second anode transfer portion 321 and the data signal line Data are in the same layer, the second anode transfer portion 321 is arranged to extend in the column direction Y. That is, the extension direction of the second anode transfer portion 321 is substantially the same as the extension direction of the data signal line Data, so as to prevent the second anode transfer portion 321 and the data signal line Data from being short-circuited.

The m-th column of pixel driving circuits Q may be electrically connected to first anodes W1 through second anode transfer portions 321, and an orthographic projection of a second anode transfer portion 321 on the substrate 10 is arranged to overlap with an orthographic projection of a first anode W1 on the substrate 10. In this way, a portion of the second anode transfer portion 321 and a portion of the first anode W1 whose orthographic projections on the substrate 10 overlap with each other, may be connected through a via hole to achieve the electrical connection between the second anode transfer portion 321 and the first anode W1. Moreover, there is no need to additionally provide a connecting portion to electrically connect the second anode transfer portion 321 to the first anode W1, which may help to save the limited space in the display substrate 100 to facilitate the layout of the display substrate 100.

The inventors have found through researches that, in the case where the orthographic projection of the second anode transfer portion 321 on the substrate 10 overlaps with the orthographic projection of the first anode W1 on the substrate 10, since the second anode transfer portion 321 does not need to be electrically connected to other anodes, the orthographic projection of the second anode transfer portion 321 on the substrate 10 is generally arranged to be non-overlapping with an orthographic projection of a second anode W2 on the substrate 10. Furthermore, the first anodes W1 and the second anodes W2 are alternately arranged in the column direction Y, and the second wiring metal layer SD2 under the first anodes W1 and the second anodes W2 has a substantially the same layout at positions corresponding to the first anodes W1 and the second anodes W2, and the difference lies in positions corresponding to the positions where the first anodes W1 and the second anodes W2 connected to the respective anode transfer portions. On this basis, a level difference will appear on the surface of the planarization layer between the second anode W2 and the second wiring metal layer SD2 away from the substrate, which increases the difficulty of forming the anode layer 211 (the second anode W2) on the planarization layer, and affects the quality of the light-emitting device O.

Based on this, in the display substrate 100 provided in some embodiments of the present disclosure, the second anode transfer portion 321 extends to a position corresponding to the second anode W2 such that the orthographic projection of the second anode transfer portion 321 on the substrate 10 overlaps with the orthographic projection of the second anode W2 on the substrate 10.

With such an arrangement, the blank space is filled with the second anode transfer portion 321 to alleviate the problem of uneven surface of the planarization layer between the second wiring metal layer SD2 and the anode layer 211 away from the substrate, which is conducive to improving the quality of the anode layer 211 formed on the surface of the planarization layer away from the substrate.

In some embodiments, as shown in FIGS. 18 and 22, in the column direction Y, orthographic projections of a first anode W1 and a second anode W2 on the substrate 10 are located between orthographic projections of two ends of a second anode transfer portion 321 on the substrate 10. Based on this, the positional relationship between the second anode transfer portion 321 and the first anode W1 and second anode W2 includes the following situations, where the two ends of the second anode transfer portion 321 include a first end near the first anode W1 and a second end near the second anode W2.

The first situation: an orthographic projection of a portion of the first end of the second anode transfer portion 321 away from the second end of the second anode transfer portion 321 on the substrate 10 substantially coincides with an orthographic projection of a portion of the first anode W1 away from the second anode W2 on the substrate 10; in addition, an orthographic projection of a portion of the second end of the second anode transfer portion 321 away from the first end of the second anode transfer portion 321 on the substrate 10 substantially coincides with an orthographic projection of a portion of the second anode W2 away from the first anode W1 on the substrate 10. That is, the portion of the first end of the second anode transfer portion 321 away from the second end of the second anode transfer portion 321 is substantially aligned with the portion of the first anode W1 away from the second anode W2, and the portion of the second end of the second anode transfer portion 321 away from the first end of the second anode transfer portion 321 is substantially aligned with the portion of the second anode W2 away from the first anode W1.

With this design, the second anode transfer portion 321 is extended to alleviate the problem of uneven surface of the planarization layer at positions corresponding the first anode W1 and the second anode W2, which is conducive to improving the quality of the anode layer 211.

It will be noted that, the term “substantially coincide with” includes absolute coincidence and approximate coincidence. That is, a spacing between the orthographic projection of the portion of the first end of the second anode transfer portion 321 away from the second end of the second anode transfer portion 321 on the substrate 10 and the orthographic projection of the portion of the first anode W1 away from the second anode W2 on the substrate 10 fluctuates without exceeding an error threshold; alternatively, it is considered that the orthographic projection of the portion of the first end of the second anode transfer portion 321 away from the second end of the second anode transfer portion 321 on the substrate 10 relatively “coincides” with the orthographic projection of the portion of the first anode W1 away from the second anode W2 on the substrate 10. The error threshold may be less than or equal to 5% of the length of the first anode W1 in the column direction Y.

Similarly, a spacing between the orthographic projection of the portion of the second end of the second anode transfer portion 321 away from the first end of the second anode transfer portion 321 on the substrate 10 and the orthographic projection of the portion of the second anode W2 away from the first anode W1 on the substrate 10 fluctuates without exceeding an error threshold; alternatively, it is considered that the orthographic projection of the portion of the second end of the second anode transfer portion 321 away from the first end of the second anode transfer portion 321 on the substrate 10 relatively “coincides” with the orthographic projection of the portion of the second anode W2 away from the first anode W1 on the substrate 10. The error threshold may be less than or equal to 5% of the length of the second anode W2 in the column direction Y.

The second situation: an orthographic projection of the first end of the second anode transfer portion 321 on the substrate 10 is located outside of the orthographic projection of the first anode W1 on the substrate 10; in addition, an orthographic projection of the second end of the second anode transfer portion 321 on the substrate 10 is located outside of the orthographic projection of the second anode W2 on the substrate 10. That is, the first end of the second anode transfer portion 321 extends to the outside of the first anode W1, and the second end of the second anode transfer portion 321 extends to the outside of the second anode W2.

With this design, the second anode transfer portion 321 is extended and extended to the outside of the corresponding anode as far as the space in the display substrate 100 allows. That is, the flatness of the planarization layer at positions corresponding to the first anode W1 and the second anode W2 may be further ensured, which is conducive to improving the quality of the anode layer 211.

The third situation: the orthographic projection of the portion of the first end of the second anode transfer portion 321 away from the second end of the second anode transfer portion 321 on the substrate 10 substantially coincides with the orthographic projection of the portion of the first anode W1 away from the second anode W2 on the substrate 10; in addition, the orthographic projection of the second end of the second anode transfer portion 321 on the substrate 10 is located outside of the orthographic projection of the second anode W2 on the substrate 10.

With this design, the second anode transfer portion 321 is extended to the outside of the corresponding anode as far as the space in the display substrate 100 allows, so that the flatness of the planarization layer at positions corresponding to the first anode W1 and the second anode W2 may be further ensured, which is conducive to improving the quality of the anode layer 211.

The fourth situation: the orthographic projection of the first end of the second anode transfer portion 321 on the substrate 10 is located outside of the orthographic projection of the first anode W1 on the substrate 10; in addition, the orthographic projection of the portion of the second end of the second anode transfer portion 321 away from the first end of the second anode transfer portion 321 on the substrate 10 substantially coincides with the orthographic projection of the portion of the second anode W2 away from the first anode W1 on the substrate 10.

With this design, the second anode transfer portion 321 is extended to the outside of the corresponding anode as far as the space in the display substrate 100 allows, so that the flatness of the planarization layer at positions corresponding to the first anode W1 and the second anode W2 may be further ensured, which is conducive to improving the quality of the anode layer 211.

In some embodiments, as shown in FIGS. 18 to 23, the multiple columns of pixel driving circuits Q further include an (m+2)-th column of pixel driving circuits Q, and the (m+2)-th column of pixel driving circuits Q are located on a side of the (m+1)-th column of pixel driving circuits Q away from the m-th column of pixel driving circuits Q. The data signal line group D electrically connected to the (m+1)-th column of pixel driving circuits Q includes at least one fourth data signal line Data2-2, and the fourth data signal line Data2-2 is located between the (m+1)-th column of pixel driving circuits Q and the (m+2)-th column of pixel driving circuits Q. The data signal line group D electrically connected to the (m+2)-th column of pixel driving circuits Q includes at least one fifth data signal line Data3-1, and the fifth data signal line Data3-1 is located between the (m+1)-th column of pixel driving circuits Q and the (m+2)-th column of pixel driving circuits Q.

The above structure is equivalent a case that the multiple data signal lines Data in the data signal line group D electrically connected to the (m+1)-th column of pixel driving circuits Q are divided into two parts; the first part of data signal lines Data is the second data signal line Data2-1, which is located between the m-th column of pixel driving circuits Q and the (m+1)-th column of pixel driving circuits Q; and the second part of data signal lines Data is the fourth data signal line Data2-2 located between the (m+1)-th column of pixel driving circuits Q and the (m+2)-th column of pixel driving circuits Q.

With such an arrangement, the multiple data signal lines Data in the data signal line group D may be arranged on two sides of the pixel driving circuit Q, and the spacing between the multiple data signal lines Data in the data signal line group D may be increased to alleviate the problem of crosstalk between the multiple data signal lines Data, which is conducive to improving the display uniformity of the display substrate 100.

In some examples, all the data signal lines Data in the data signal line group D electrically connected to the (m+2)-th column of pixel driving circuits Q are fifth data signal lines Data3-1. That is, all the data signal lines Data (the fifth data signal lines Data3-1) in the data signal line group D electrically connected to the (m+2)-th column of pixel driving circuits Q are located between the (m+1)-th column of pixel driving circuits Q and the (m+2)-th column of pixel driving circuits Q. All the data signal lines Data in the data signal line group D are centrally arranged, which may simplify the layout of the data signal lines Data in the display substrate 100.

In some other examples, a part of the data signal lines Data in the data signal line group D electrically connected to the (m+2)-th column of pixel driving circuits Q is a fifth data signal line Data3-1. That is, another part of the data signal lines Data in the data signal line group D electrically connected to the (m+2)-th column of pixel driving circuits Q is a sixth data signal line Data3-2.

This is equivalent to a case that the multiple data signal lines Data in the data signal line group D electrically connected to the (m+2)-th column of pixel driving circuits Q are divided into two parts; the first part of data signal lines Data is the fifth data signal line Data3-1, which is located between the (m+1)-th column of pixel driving circuits Q and the (m+2)-th column of pixel driving circuits Q; and the second part of data signal lines Data is the sixth data signal line Data3-2, which is located between the (m+2)-th column of pixel driving circuits Q and the (m+3)-th column of pixel driving circuits Q.

In order to alleviate the problem of crosstalk between the fourth data signal line Data2-2 and the fifth data signal line Data3-1, as shown in FIGS. 18 to 23, in the anode layer 211 of the display substrate 100 provided in some embodiments of the present disclosure, multiple anode transfer lines 30 electrically connected to the (m+2)-th column of pixel driving circuits Q include at least one third anode transfer line 33, the third anode transfer line 33 includes a third anode transfer portion 331, and the third anode transfer portion 331 is in the same layer as the data signal line Data. In the row direction X, the third anode transfer portion 331 is located between the fourth data signal line Data2-2 electrically connected to the (m+1)-th column of pixel driving circuits Q and the fifth data signal line Data3-1 electrically connected to the (m+2)-th column of pixel driving circuits Q.

The third anode transfer portion 331 and the data signal line Data are disposed in the same layer, so that there is small number of film layers sandwiched between the third anode transfer portion 331 and the anode layer 211, which may facilitate the electrical connection between the third anode transfer portion 331 and the anode in the anode layer 211. Moreover, the third anode transfer portion 331 and the data signal line Data are disposed in the same layer, so that the third anode transfer portion 331 and the data signal line Data may be formed in a single patterning process, which may be conducive to simplifying the manufacturing processes and improving the yield. However, the embodiments of the present disclosure are not limited to the above, and the third anode transfer portion 331 and the data signal line Data may be formed separately in two manufacturing processes.

It will be noted that, the term “same layer” refers to a layer structure formed through a single patterning process by using a same mask in which a film layer for forming a specific pattern is formed by using a same film-forming process. Depending on different specific patterns, the single patterning process may include multiple times of exposure, development or etching, and the specific pattern formed in the layer structure may be continuous or discontinuous, and these specific patterns may also be at different heights or have different thicknesses.

On the basis that the third anode transfer portion 331 and the data signal line Data are disposed in the same layer, in the case where the third anode transfer portion 331 is disposed between the fourth data signal line Data2-2 and the fifth data signal line Data3-1, a space needs to be reserved between the fourth data signal line Data2-2 and the fifth data signal line Data3-1 to arrange the third anode transfer portion 331. Thus, it helps to increase the spacing between the fourth data signal line Data2-2 and the fifth data signal line Data3-1 and reduce the parasitic capacitance generated between the fourth data signal line Data2-2 and the fifth data signal line Data3-1. As a result, the problem that the potential of the data signal line Data jumps when an adjacent data signal line Data transmits a data writing signal may be alleviated, thereby alleviating the problem of lateral crosstalk in the display substrate 100.

Furthermore, the third anode transfer portion 331 is configured to have a constant voltage potential. Thus, in the case where the third anode transfer portion 331 is disposed between the fourth data signal line Data2-2 and the fifth data signal line Data3-1, the third anode transfer portion 331 may be used to isolate the fourth data signal line Data2-2 from the fifth data signal line Data3-1, so as to further reduce the parasitic capacitance generated between the fourth data signal line Data2-2 and the fifth data signal line Data3-1 to alleviate the problem of crosstalk between the fourth data signal line Data2-2 and the fifth data signal line Data3-1. The principle of configuring the third anode transfer portion 331 to have a constant voltage potential is the same as the principle of configuring the first anode transfer portion 311 to have a constant voltage potential, which will not be repeated here.

In some examples, the third anode transfer portion 331 is electrically connected to a third anode W3, and in the row direction X, the third anode W3 overlaps with a first anode W1, and the third anode W3 overlaps with a second anode W2.

The (m+2)-th column of pixel driving circuits Q may be electrically connected to third anodes W3 through third anode transfer portions 331, and an orthographic projection of a third anode transfer portion 331 on the substrate 10 is arranged to overlap with an orthographic projection of a third anode W3 on the substrate 10. In this way, a portion of the third anode transfer portion 331 and a portion of the third anode W3, whose orthographic projections on the substrate 10 overlap with each other, may be connected through a via hole to achieve the electrical connection between the third anode transfer portion 331 and the third node W3. Moreover, there is no need to additionally provide a connecting portion to electrically connect the third anode transfer portion 331 to the third node W3, which may help to save the limited space in the display substrate 100 and facilitate the layout of the display substrate 100.

The inventors have found through research that, in the case where the orthographic projection of the third anode transfer portion 331 on the substrate 10 overlaps with the orthographic projection of the third anode W3 on the substrate 10, the third anode transfer portion 331 only needs to be electrically connected to the third anode W3 to achieve driving a light-emitting device O corresponding to the third anode W3 to emit light.

Based on this, in the display substrate 100 provided in some embodiments of the present disclosure, in the column direction Y, a border of the orthographic projection of the third anode transfer portion 331 on the substrate 10 is arranged to substantially coincide with a border of the orthographic projection of the third anode W3 on the substrate 10.

It will be noted that, the term “substantially coincide with” includes absolute coincidence and approximate coincidence. That is, in the column direction Y, a spacing between the border of the orthographic projection of the third anode transfer portion 331 on the substrate 10 and the border of the orthographic projection of the third anode W3 on the substrate 10 fluctuates without exceeding an error threshold; alternatively, it is considered that the border of the orthographic projection of the third anode transfer portion 331 on the substrate 10 relatively “coincide” with the border of the orthographic projection of the third anode W3 on the substrate 10 in the column direction Y. The error threshold may be less than or equal to 10% of the length of the third anode W3 in the column direction Y.

This design is equivalent to a case that the third anode transfer portion 331 extends to be consistent with the length of the third anode W3 in the column direction Y, so as to alleviate the problem of uneven surface of the planarization layer at a position corresponding to the third anode W3 due to the small length of the third anode transfer portion 331, thereby helping to improve the quality of the anode layer 211.

In addition, since the third anode transfer portion 331 and the data signal line Data are in the same layer, the third anode transfer portion 331 is arranged to extend in the column direction Y. That is, the extension direction of the third anode transfer portion 331 is arranged to be substantially the same as the extension direction of the data signal line Data, which may prevent the third anode transfer portion 331 and the data signal line Data from being short-circuited.

In some embodiments, as shown in FIGS. 18 and 22, in the column direction Y, the orthographic projection of the third anode W3 on the substrate 10 is located between orthographic projections of two ends of the third anode transfer portion 331 on the substrate 10. On this basis, in addition to the above “in the column direction Y, the border of the orthographic projection of the third anode transfer portion 331 on the substrate 10 substantially coincide with the border of the orthographic projection of the third anode W3 on the substrate 10”, the positional relationship between the third anode transfer portion 331 and the third anode W3 further includes the following situations.

The first situation: an orthographic projection of one of the two ends of the third anode transfer portion 331 on the substrate 10 is located outside of the orthographic projection of the third anode W3 on the substrate 10.

The second situation: the orthographic projections of two ends of the third anode transfer portion 331 on the substrate 10 are both located outside of the orthographic projection of the third anode W3 on the substrate 10.

With this design, the third anode transfer portion 331 is extended to the outside of the corresponding anode as far as the space in the display substrate 100 allows. That is, the flatness of the planarization layer at the position corresponding to the third anode W3 may be further ensured, which is conducive to improving the quality of the anode layer 211.

The above mainly introduces the positions of the data signal lines and the anode transfer portions in conjunction with relevant drawings, and the positions of the transistors in the pixel driving circuit Q and multiple connecting portions will be introduced below in conjunction with relevant drawings.

In some embodiments, as shown in FIGS. 18 to 22, the pixel driving circuit Q includes: a first reset transistor T1, a compensation transistor T2, a driving transistor T3, a data writing transistor T4, a first light-emitting control transistor T5, a second light-emitting control transistor T6, and a second reset transistor T7.

In the column direction Y, the first reset transistor T1 and the compensation transistor T2 are located on a same side of the driving transistor T3, the data writing transistor T4 and the first light-emitting control transistor T5 are located on a same side of the driving transistor T3, and the first reset transistor T1 and the data writing transistor T4 are respectively located on two sides of the driving transistor T3, which is equivalent to that the first reset transistor T1 and the compensation transistor T2 are located in the upper part of the pixel driving circuit Q, and the data writing transistor T4 and the first light-emitting control transistor T5 are located in the lower part of the pixel driving circuit Q.

On this basis, the data writing transistor T4 is set to be located on a side of the first light-emitting control transistor T5 away from the driving transistor T3. This is equivalent to arranging the data writing transistor T4 at the edge of the pixel driving circuit Q, which facilitates the electrical connection between the data writing transistor T4 and a data signal line Data, and prevents the electrical connection between the data writing transistor T4 and the data signal line Data from restricting the layout of other transistors in the pixel driving circuit Q, so as to improve the layout flexibility of the display substrate 100.

In some examples, the first electrode a1 of the first reset transistor T1 is electrically connected to the first initialization signal line Vinit1, and in the column direction Y, the first initialization signal line Vinit1 is located on a side of the first reset transistor T1 away from the compensation transistor T2. This is equivalent to arranging the first initialization signal line Vinit1 at the edge of the pixel driving circuit Q, which facilitates the layout of the first initialization signal line Vinit1 and prevents the first initialization signal line Vinit1 from being short-circuited with other transistors in the pixel driving circuit Q.

In some examples, the control electrode of the first reset transistor T1 is electrically connected to the third scanning signal line G3. The control electrode of the compensation transistor T2 is electrically connected to the second scanning signal line G2. The second scanning signal line G2 and the third scanning signal line G3 are located in the first wiring metal layer SD1.

In the column direction Y, the second scanning signal line G2 is located between the third scanning signal line G3 and the driving transistor T3. In this way, the third scanning signal line G3 and the first reset transistor T1 may be correspondingly arranged, and the second scanning signal line G2 and the compensation transistor T2 may be correspondingly arranged, which facilitates the layout of the second scanning signal line G2 and the third scanning signal line G3.

In some examples, the first wiring metal layer SD1 includes a plurality of conductive portions. The plurality of conductive portions include a first conductive portion PAD1, and the first conductive portion PAD1 is used to connect the first electrode a1 of the first reset transistor T1 to the first initialization signal line Vinit1.

Since the first electrode a1 of the first reset transistor T1 is located on a side of the control electrode c1 of the first reset transistor T1 away from the compensation transistor T2, the first conductive portion PAD1 may be disposed on a side of the third scanning signal line G3 away from the second scanning signal line G2 to facilitate the layout of the first conductive portion PAD1 and the third scanning signal line G3 and prevent the first conductive portion PAD1 and the third scanning signal line G3 from crossing each other and being short-circuited.

In some examples, the plurality of conductive portions further include a second transfer portion PAD2, an end of the second transfer portion PAD2 is electrically connected to the control electrode c3 of the driving transistor T3, and the other end of the second transfer portion PAD2 is electrically connected to the second electrode b2 of the compensation transistor T2 and the second electrode b1 of the first reset transistor T1, so that the control electrode c3 of the driving transistor T3 is electrically connected to the second electrode b2 of the compensation transistor T2 and the second electrode b1 of the first reset transistor T1.

The second connecting portion PAD2 is located on a side of the second scanning signal line G2 proximate to the driving transistor T3, which is equivalent to arranging the second connecting portion PAD2 in a space defined by the first reset transistor T1, the compensation transistor T2 and the driving transistor T3, so as to facilitate the electrical connection of the second connecting portion PAD2 to the first reset transistor T1, the compensation transistor T2 and the driving transistor T3, thereby achieving the electrical connection of the control electrode c3 of the driving transistor T3 to the second electrode b2 of the compensation transistor T2 and the second electrode b1 of the first reset transistor T1.

In some examples, the plurality of conductive portions further include a third transfer portion PAD3, an end of the third transfer portion PAD3 is electrically connected to the first electrode a3 of the driving transistor T3, and the other end of the third transfer portion PAD3 is electrically connected to the second electrode b4 of the data writing transistor T4 and the second electrode b5 of the first light-emitting control transistor T5, so that the first electrode a3 of the driving transistor T3 is electrically connected to the second electrode b4 of the data writing transistor T4 and the second electrode b5 of the first light-emitting control transistor T5.

The third transfer portion PAD3 is located in a space defined by the driving transistor T3, the data writing transistor T4 and the first light-emitting control transistor T5, which facilitates the electrical connection of the third transfer portion PAD3 to the driving transistor T3, the data writing transistor T4 and the first light-emitting control transistor T5, thereby achieving the electrical connection of the first electrode a3 of the driving transistor T3 to the second electrode b4 of the data writing transistor T4 and the second electrode b5 of the first light-emitting control transistor T5.

In some embodiments, as shown in FIGS. 18 to 22, in the case where the pixel driving circuit Q further includes the second light-emitting control transistor T6 and the second reset transistor T7, the anode transfer line 30 further includes a fourth conductive portion PAD4 located in the first wiring metal layer SD1; an end of the fourth conductive portion PAD4 of the anode transfer line 30 is electrically connected to the second electrode of the second light-emitting control transistor T6 and the second electrode of the second reset transistor T7, and the other end of the fourth conductive portion PAD4 may be electrically connected to an anode transfer portion (the first anode transfer portion, the second anode transfer portion or the third anode transfer portion) of the same anode transfer line 30.

In the column direction Y, the fourth conductive portion PAD4 is located between the enable signal line EM and the first scanning signal line G1, and the fourth conductive portion PAD4 is located in a space defined by the second light-emitting control transistor T6, the second reset transistor T7, the enable signal line EM and the first scanning signal line G1, which facilitates the electrical connection of the fourth conductive portion PAD4 to the second light-emitting control transistor T6 and the second reset transistor T7.

In some embodiments, as shown in FIGS. 18 to 22, in the column direction Y, the data writing transistor T4, the first light-emitting control transistor T5, the second light-emitting control transistor T6 and the second reset transistor T7 in the pixel driving circuit Q are all located on a same side of the driving transistor T3. The second reset transistor T7 is located on a side of the second light-emitting control transistor T6 away from the driving transistor T3.

On this basis, the second light-emitting control transistor T6 is adjacent to the first light-emitting control transistor T5 in the row direction X, and the second reset transistor T7 is adjacent to the data writing transistor T4 in the row direction X.

The control electrode of the first light-emitting control transistor T5 is electrically connected to the enable signal line EM, and the control electrode of the second light-emitting control transistor T6 is electrically connected to the enable signal line EM. Therefore, the second light-emitting control transistor T6 is arranged to adjacent to the first light-emitting control transistor T5 in the row direction X, so that the second light-emitting control transistor T6 and the first light-emitting control transistor T5 may be arranged in the extension direction of the enable signal line EM. On this basis, the enable signal line EM does not need to be arranged in a winding manner, which facilitates the electrical connection of the enable signal line EM to the control electrode of the first light-emitting control transistor T5 and the control electrode of the second light-emitting control transistor T6.

In addition, in some examples, the enable signal line EM is located in the first gate metal layer Gate1, and the enable signal line EM may include a first portion and a second portion, the first portion of the enable signal line EM may also serve as the control electrode c5 of the first light-emitting control transistor T5, and the second portion of the enable signal line EM may also serve as the control electrode c6 of the second light-emitting control transistor T6. This structure helps to simplify the structure of the pixel driving circuit Q.

The control electrode of the data writing transistor T4 is electrically connected to the first scanning signal line G1, and the control electrode of the second reset transistor T7 is electrically connected to the first scanning signal line G1. Therefore, the second reset transistor T7 is arranged to adjacent to the data writing transistor T4 in the row direction X, so that the second reset transistor T7 and the data writing transistor T4 may be arranged in the extension direction of the first scanning signal line G1. On this basis, the first scanning signal line G1 does not need to be arranged in a winding manner, which facilitates the electrical connection of the first scanning signal line G1 to the control electrode of the second reset transistor T7 and the control electrode of the data writing transistor T4.

In some examples, the first scanning signal line G1 is located in the first gate metal layer Gate1, and the formed first scanning signal line G1 has a large impedance.

Based on this, the first wiring metal layer SD1 of the display substrate 100 may further include a first auxiliary signal line F1, and the first auxiliary signal line F1 is connected in parallel to the first scanning signal line G1. In this way, the resistance of the first scanning signal line G1 may be reduced, which alleviates the problem of the large impedance of the first scanning signal line G1 to improve the uniformity of the display substrate 100.

In some examples, an orthographic projection of the first auxiliary signal line F1 on the substrate 10 at least partially overlaps with an orthographic projection of the first scanning signal line G1 on the substrate 10. The first auxiliary signal line F1 and the first scanning signal line G1 may be electrically connected to each other at overlapping portions thereof through a via hole, so that there is no need to use other connecting portions to electrically connect the first auxiliary signal line F1 to the first scanning signal line G1, which may reduce the space occupied in the display substrate 100.

For example, the orthographic projection of the first auxiliary signal line F1 on the substrate 10 partially overlaps with the orthographic projection of the first scanning signal line G1 on the substrate 10.

For another example, the orthographic projection of the first auxiliary signal line F1 on the substrate 10 is located within the orthographic projection of the first scanning signal line G1 on the substrate 10.

With either of the above designs, the first auxiliary signal line F1 and the first scanning signal line G1 may be electrically connected to each other at the overlapping portions thereof through a via hole, thereby simplifying the connection between the first auxiliary signal line F1 and the first scanning signal line G1.

In some embodiments, as shown in FIG. 6 and FIGS. 18 to 22, the pixel driving circuits Q in a same column includes a first part of pixel driving circuits Q1 and a second part of pixel driving circuits Q2. The first part of pixel driving circuits Q1 is electrically connected to a second part of data signal lines Data-2, and the second part of pixel driving circuits Q2 is electrically connected to a first part of data signal lines Data-1. The data writing transistor T4 of the first part of pixel driving circuits Q1 is located between the second reset transistor T7 of the first part of pixel driving circuits Q1 and the second part data signal line Data-2, and the data writing transistor T4 of the second part of pixel driving circuits Q2 is located on a side of the second reset transistor T7 of the second part of pixel driving circuits Q2 away from the first part of data signal lines Data-1.

In FIGS. 18 to 22, the pixel driving circuits Q in the first row of pixel driving circuits are each the first part of pixel driving circuits Q1 in each column, and the pixel driving circuits Q in the second row of pixel driving circuits are each the second part of pixel driving circuits Q2 in each column.

At least one pixel driving circuit Q in the second part of pixel driving circuits Q2 includes a first data transfer portion L1 located in the first wiring metal layer SD1, and the first data transfer portion L1 is used to electrically connect the pixel driving circuit Q to a data signal line Data. The first data transfer portion L1 includes an avoiding portion R1, and the avoiding portion R1 is located on a side of the second reset transistor T7 away from the second light-emitting control transistor T6.

For the pixel driving circuit Q in the second part of pixel driving circuits Q2, since the second reset transistor T7 is located between the data writing transistor T4 and the first part of data signal lines Data-1 to which the data writing transistor T4 needs to be electrically connected, with the provision of the avoiding portion R1 in the first data transfer portion L1, the first data transfer portion L1 for connecting the data writing transistor T4 and the first part of data signal lines Data-1 may avoid the second reset transistor T7, so as to prevent the first data transfer portion L1 and the second reset transistor T7 from being short-circuited.

In some examples, the avoiding portion R1 may be in a shape of a concave, or the avoiding portion R1 may be in other shapes that are convex toward a side away from the second reset transistor T7, and the embodiments of the present disclosure are not limited thereto.

In some embodiments, as shown in FIGS. 18 to 22, the first electrode a7 of the second reset transistor T7 is electrically connected to a second initialization signal line Vinit2. The plurality of conductive portions in the first wiring metal layer SD1 may further include a first connecting portion PAD5, and the first connecting portion PAD5 is used to connect the first electrode a7 of the second reset transistor T7 to the second initialization signal line Vinit2, so as to achieve the electrical connection between the first electrode a7 of the second reset transistor T7 and the second initialization signal line Vinit2 that are located in different layers.

In the column direction Y, the second initialization signal line Vinit2 is located on a side of the second reset transistor T7 away from the second light-emitting control transistor T6, and the avoiding portion R1 is located on a side of the first connecting portion PAD5 away from the second light-emitting control transistor T6.

The first data transfer portion L1 and the first connecting portion PAD5 are both located in the first wiring metal layer SD1. Therefore, the avoiding portion R1 is arranged on a side of the first connecting portion PAD5 away from the second light-emitting control transistor T6, so that the first data transfer portion L1 may avoid the first connecting portion PAD5 by using the avoiding portion R1, so as to prevent the first data connecting portion L1 and the first connecting portion PAD5 from being short-circuited.

In some embodiments, as shown in FIGS. 18 to 22, the plurality of conductive portions in the first wiring metal layer SD1 in the driving circuit layer 20 further include a second connecting portion PAD6. An end of the second connecting portion PAD6 is electrically connected to the first plate Cst-1 of the storage capacitor Cst and the first electrode a5 of the first light-emitting control transistor T5, and the other end of the second connecting portion PAD6 is electrically connected to the first power signal line VDD. In this way, the first power signal line VDD is electrically connected to the first plate Cst-1 of the storage capacitor Cst and the first electrode a5 of the first light-emitting control transistor T5.

In some embodiments, as shown in FIGS. 18 to 22, a plurality of first power signal lines VDD are arranged in the row direction X and extend in the column direction Y. In the row direction X, the first part of data signal lines Data-1 and the second part of data signal lines Data-2 are respectively located on two sides of the first power signal line VDD. With this arrangement, the first power signal line VDD may be used to increase the spacing between the first part of data signal lines Data-1 and the second part of data signal lines Data-2, so as to reduce the parasitic capacitance between the first part of data signal lines Data-1 and the second part of data signal lines Data-2 to reduce the crosstalk between the first part of data signal lines Data-1 and the second part of data signal lines Data-2. Moreover, the first power signal line VDD is configured to have a constant voltage signal, which may further reduce the crosstalk between the first part of data signal lines Data-1 and the second part of data signal lines Data-2, thereby improving the display effect of the display substrate 100.

In some embodiments, as shown in FIGS. 18 to 22, in the row direction X, the avoiding portion R1 of the first data transfer portion L1 crosses over the first power signal line VDD electrically connected to the second part of pixel driving circuits Q2, which is equivalent to a case that the first power signal line VDD is located between the data writing transistor T4 and the first part of data signal lines Data-1 in the row direction X. Thus, the first power signal line VDD is arranged in the middle of the pixel driving circuit Q, which facilitates the electrical connection between the first power signal line VDD and the storage capacitor Cst located in the middle of the pixel driving circuit Q, thereby facilitating the electrical connection between the first power signal line VDD and the second connecting portion PAD6 to simplify the wiring layout of the display substrate 100.

In addition, the extension direction of the first power signal line VDD intersects with the extension direction of the first data transfer portion L1. Therefore, the first data transfer portion L1 and the first power signal line VDD are arranged in different layers, so as to achieve that the avoiding portion R1 of the first data transfer portion L1 crosses over the first power signal line VDD electrically connected to the second part of pixel driving circuits Q2 to prevent the avoiding portion R1 of the first data transfer portion L1 from being short-circuited with the first power signal line VDD electrically connected to the second part of pixel driving circuits Q2.

It will be noted that, the above “cross over” means that an orthographic projection of the avoiding portion R1 of the first data transfer portion L1 on the substrate 10 overlaps with an orthographic projection of the first power signal line VDD electrically connected to the second part of pixel driving circuits Q2 on the substrate 10.

At least one pixel driving circuit Q in the first part of pixel driving circuits Q1 includes a second data transfer portion L2 located in the first wiring metal layer SD1. Since the data writing transistor T4 of the first part of pixel driving circuits Q1 is located between the second reset transistor T7 of the first part of pixel driving circuit Q1 and the second part of data signal lines Data-2, there is no other transistors provided between the data writing transistor T4 of the first part of pixel driving circuits Q1 and the second part of data signal lines Data-2. Thus, in the row direction, the spacing between the data writing transistor T4 of the first part of pixel driving circuits Q1 and the second part of data signal lines Data-2 electrically connected to the first part of pixel driving circuits Q1 may be less than the spacing between the data writing transistor T4 of the second part of pixel driving circuits Q2 and the first part of data signal lines Data-1 electrically connected to the second part of pixel driving circuits Q2.

On this basis, in the row direction X, the length of the second data transfer portion L2 is less than the length of the first data transfer portion L1. In this way, the space occupied by the second data transfer portion L2 in the display substrate 100 may be reduced, which may help to save the space in the display substrate 100 to facilitate the layout of other wirings in the display substrate 100.

In some examples, the first data transfer portion L1 includes a first portion and a second portion; an orthographic projection of the first portion of the first data transfer portion L1 on the substrate 10 overlaps with an orthographic projection of a first electrode a4 of a data writing transistor T4 on the substrate 10, so that the first portion of the first data transfer portion L1 is electrically connected to the first electrode a4 of the data writing transistor T4 through a via hole, which simplifies the connection between the first portion of the first data transfer portion L1 and the first electrode a4 of the data writing transistor T4; in addition, an orthographic projection of the second portion of the first data transfer portion L1 on the substrate 10 overlaps with an orthographic projection of the first part of data signal lines Data-1 on the substrate 10, so that the second portion of the first data transfer portion L1 is electrically connected to the first part of data signal lines Data-1 through a via hole, which simplifies the connection between the second portion of the first data transfer portion L1 and the first part of data signal lines Data-1.

For example, the orthographic projection of the first portion of the first data transfer portion L1 on the substrate 10 substantially coincides with the orthographic projection of the first electrode a4 of the data writing transistor T4 on the substrate 10, and the orthographic projection of the first part of data signal lines Data-1 on the substrate 10 covers the orthographic projection of the second portion of the first data transfer portion L1 on the substrate 10.

On this basis, the dimension of the first data transfer portion L1 may be further reduced, which helps to reduce the space occupied by the first data transfer portion L1 in the display substrate 100, thereby saving the space in the display substrate 100 and facilitating the layout of other wirings in the display substrate 100.

In some embodiments, referring to FIG. 18, the display substrate 100 further includes a plurality of first total initialization signal lines V1 and second total initialization signal lines, and the first total initialization signal lines V1 and the second total initialization signal lines all extend in the column direction Y. In the row direction X, three adjacent columns of pixel driving circuits Q constitute a pixel driving circuit unit column. The first initialization signal lines Vinit1 electrically connected to all the pixel driving circuits Q in the pixel driving circuit unit column may be electrically connected to a first total initialization signal line V1, so as to use the first total initialization signal line V1 to provide a signal to each first initialization signal line Vinit1 in the pixel driving circuit unit column. In addition, the second initialization signal lines Vinit2 electrically connected to all the pixel driving circuit Q in the pixel driving circuit unit column may be electrically connected to a second total initialization signal line (not shown in the figures), so as to use the second total initialization signal line to provide a signal to each second initialization signal line Vinit2 in the pixel driving circuit unit column. Thus, it is conducive to providing signals to the first initialization signal lines Vinit1 and the second initialization signal lines Vinit2 to simplify the layout of the display substrate 100.

In some examples, the first total initialization signal line V1 and the second total initialization signal line may be respectively located on two sides of the pixel driving circuit unit column.

Thus, it is possible to avoid the problem of short circuit between signal lines caused by too many signal lines (the first total initialization signal line V1 and the second total initialization signal line) disposed on a side of the pixel driving circuit unit column, thereby facilitating the improvement of the quality of the display substrate 100.

However, the embodiments of the present disclosure are not limited to the above. In some other examples, the first total initialization signal line V1 and the second total initialization signal line may be located on a same side of the pixel driving circuit unit column, which improves the layout flexibility of the wirings in the display substrate 100.

What is mainly introduced above in conjunction with relevant drawings is the layout of the pixel driving circuits Q and the data signal lines Data in the case where the driving circuit layer 20 includes the first semiconductor layer POLY, the first gate metal layer Gate1, the second gate metal layer Gate2, the first wiring metal layer SD1 and the second wiring metal layer SD2. The following will introduce the layout of the pixel driving circuits Q and the data signal lines Data in the case where the driving circuit layer 20 includes the first semiconductor layer POLY, the first gate metal layer Gate1, the second gate metal layer Gate2, the first wiring metal layer SD1, the second wiring metal layer SD2 and a third wiring metal layer SD3 in conjunction with relevant drawings.

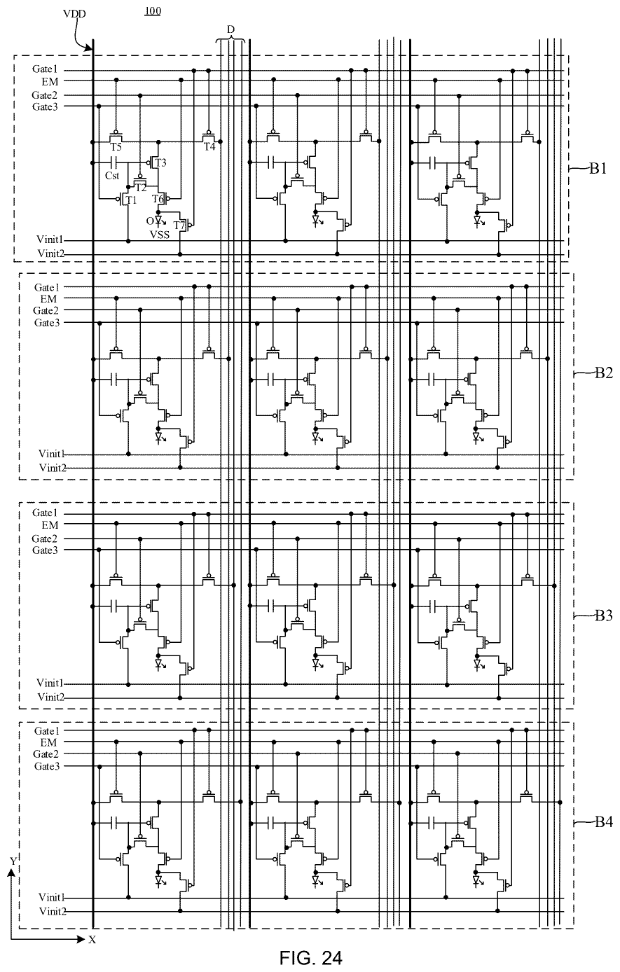

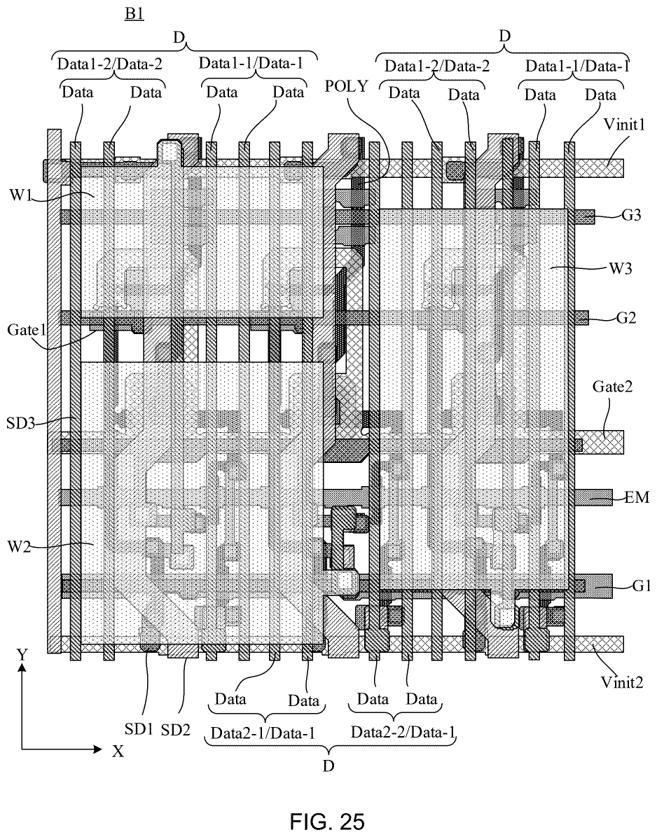

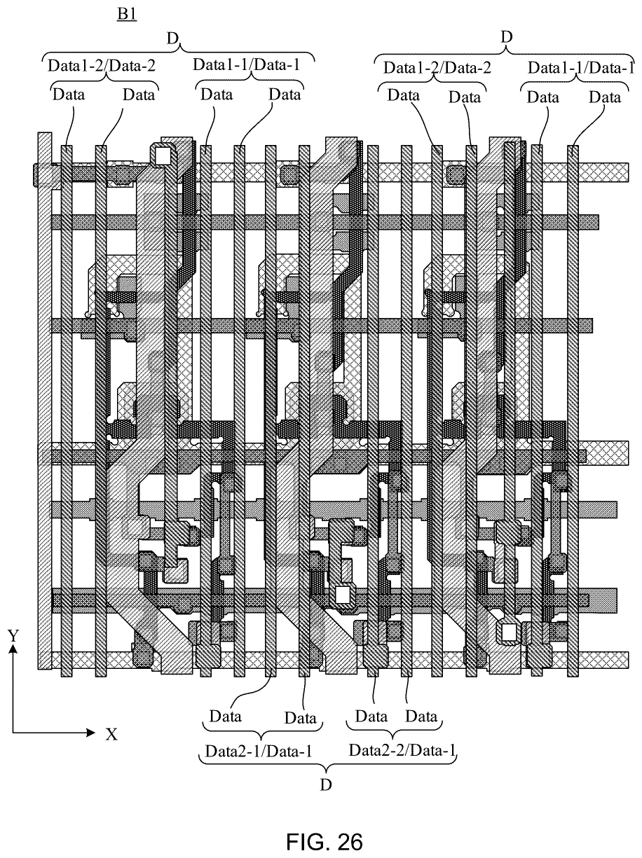

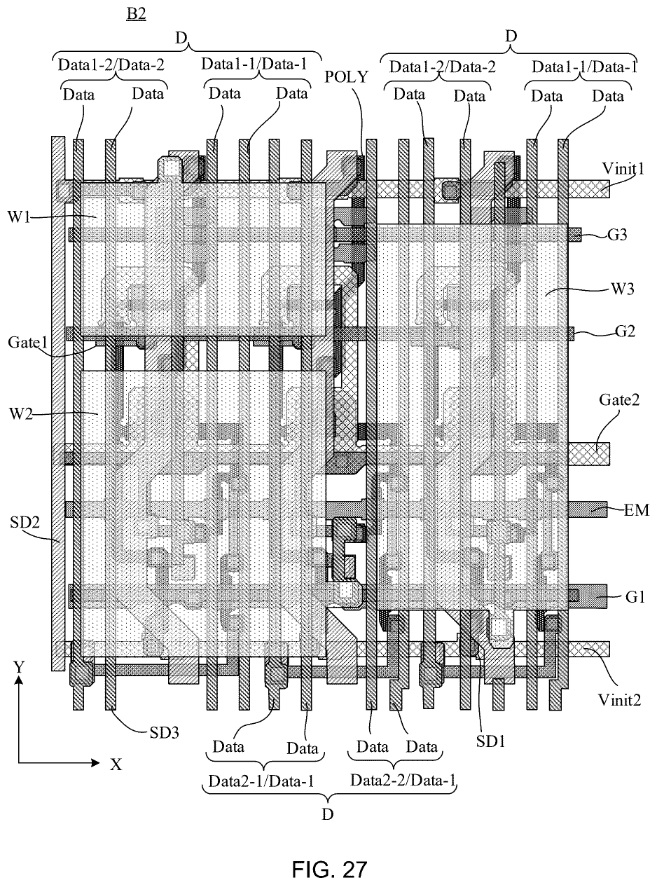

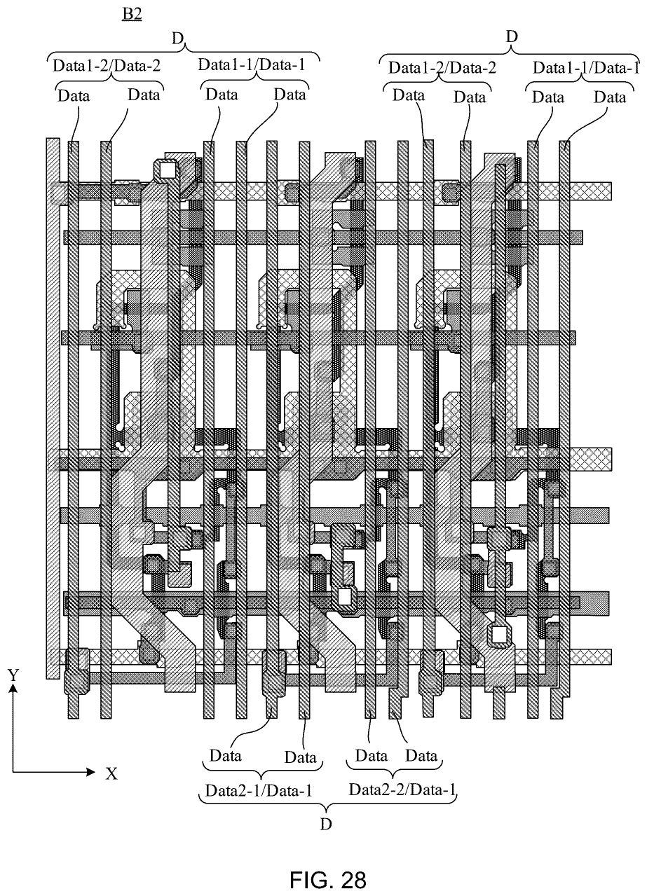

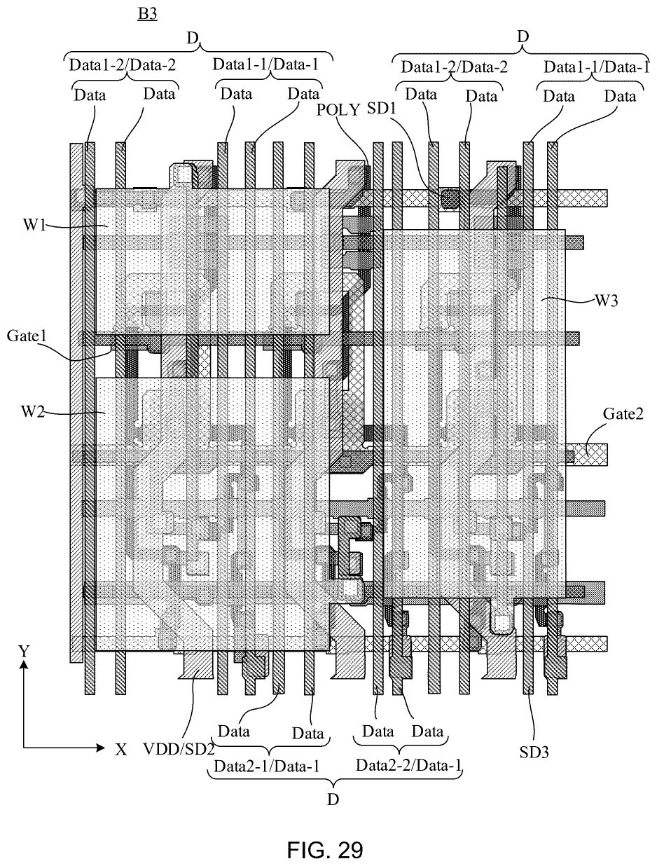

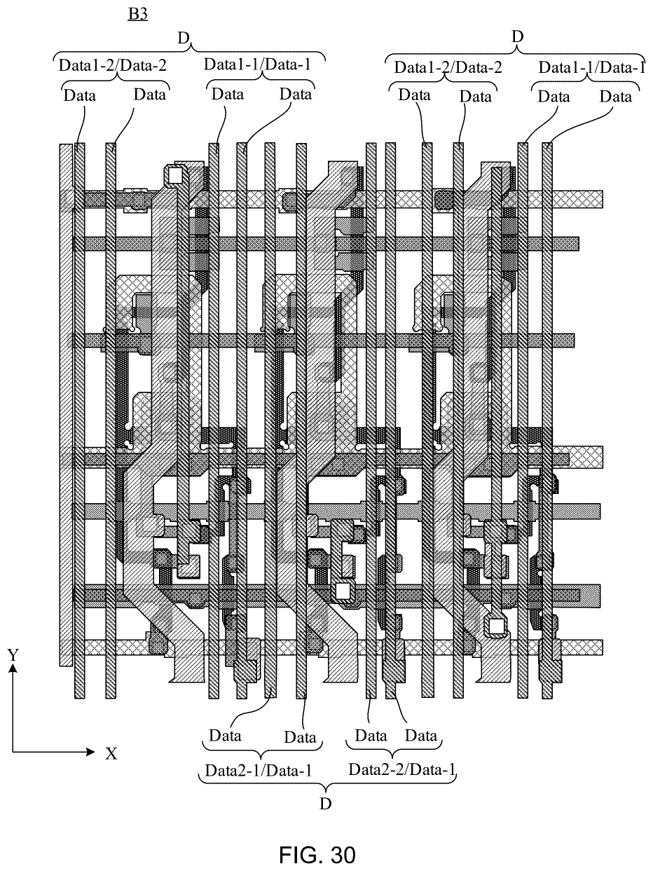

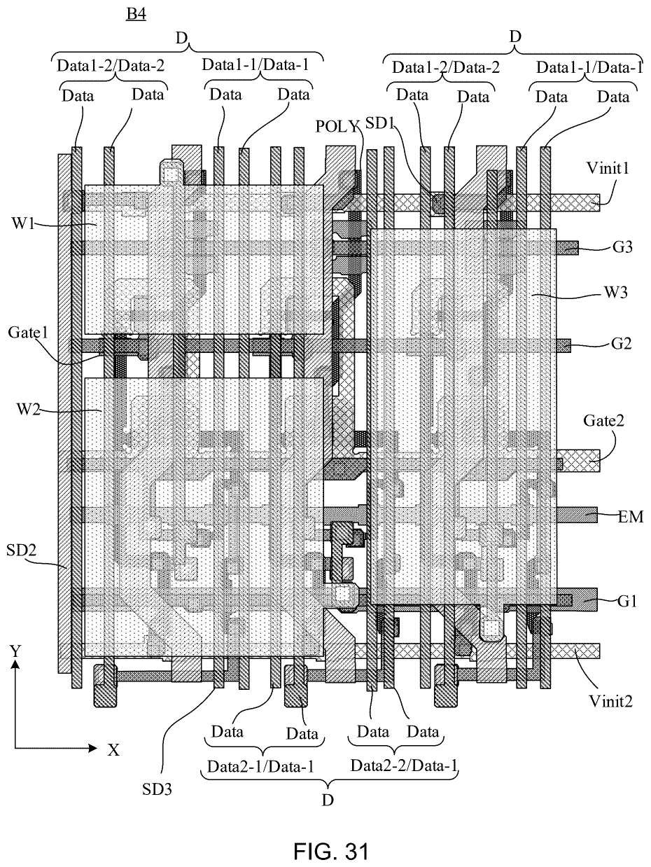

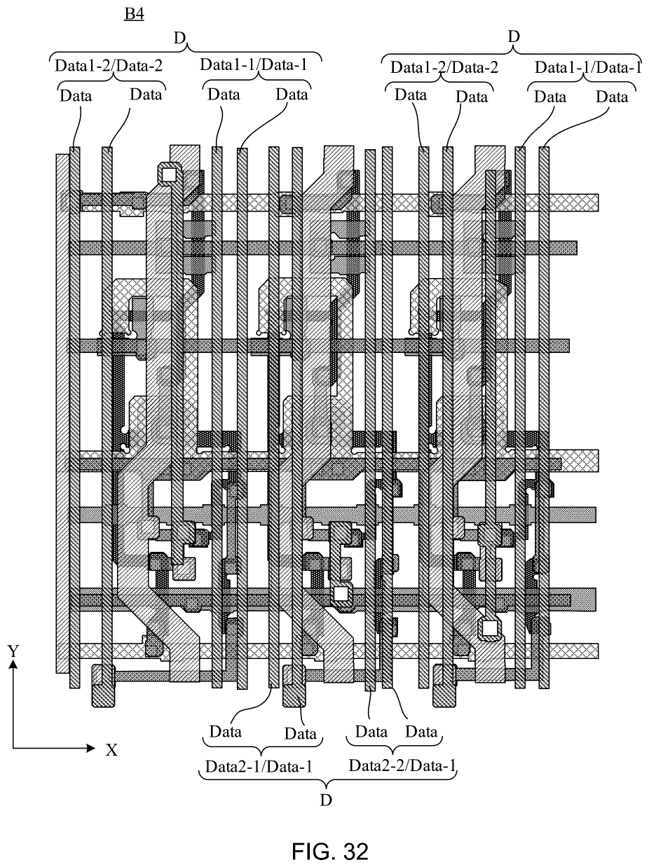

FIG. 24 is an equivalent circuit diagram of a plurality of pixel driving circuits in a display substrate, in accordance with some other embodiments; FIG. 25 is a diagram showing a partial connection between a pixel driving circuit and a light-emitting layer in the region B1 in FIG. 24; FIG. 26 is a partial film layer structural diagram in the region B1 in FIG. 24; FIG. 27 is a diagram showing a partial connection between a pixel driving circuit and a light-emitting layer in the region B2 in FIG. 24; FIG. 28 is a partial film layer structural diagram in the region B2 in FIG. 24; FIG. 29 is a diagram showing a partial connection between a pixel driving circuit and a light-emitting layer in the region B3 in FIG. 24; FIG. 30 is a partial film layer structural diagram in the region B3 in FIG. 24; FIG. 31 is a diagram showing a partial connection between a pixel driving circuit and a light-emitting layer in the region B4 in FIG. 24; FIG. 32 is a partial film layer structural diagram in the region B4 in FIG. 24.

In some embodiments, as shown in FIGS. 25 to 32, the driving circuit layer 20 includes the first semiconductor layer POLY, the first gate metal layer Gate1, the second gate metal layer Gate2, the first wiring metal layer SD1, the second wiring metal layer SD2 and the third wiring metal layer SD3. The anode layer 211 is located on a side of the third wiring metal layer SD3 away from the second wiring metal layer SD2.

Based on this, multiple data signal lines Data in a data signal group D may be located in the second wiring metal layer SD2 and/or the third wiring metal layer SD3. For the positions of the multiple data signal lines Data in a data signal group D, there may exist following three situations.

The first situation: as shown in FIG. 7, the multiple data signal lines Data in the data signal group D are all located in the second wiring metal layer SD2. That is, the plurality of data signal line groups D are all located in the second wiring metal layer SD2.

With this structure, the data signal lines Data may be formed together with other conductive portions in the second wiring metal layer SD2 in a single patterning process, which may simplify the manufacturing process of the display substrate 100.

The second situation: as shown in FIGS. 25 to 28, the multiple data signal lines Data in the data signal group D are all located in the third wiring metal layer SD3. That is, the plurality of data signal line groups D are all located in the third wiring metal layer SD3.

The plurality of data signal line groups D are disposed in the third wiring metal layer SD3, which may not only prevent the plurality of data signal line groups D from being short-circuited with the multiple conductive portions in the second wiring metal layer SD2, but also increase the flexibility of providing multiple data signal line groups D to facilitate the wiring layout of the display substrate 100.

The third situation: a part of data signal lines Data in a data signal group D are located in the second wiring metal layer SD2, and another part of data signal lines Data in the same data signal group D are located in the third wiring metal layer SD3.

The multiple data signal lines Data are arranged in different layers, which may not only facilitate increasing the number of data signal lines Data to increase the refresh duration of the pixel driving circuit, but also increase the flexibility of providing multiple data signal line groups D to facilitate the wiring layout of the display substrate 100. In addition, the data signal lines Data located in the second wiring metal layer SD2 may be formed together with other conductive portions in the second wiring metal layer SD2 in a single patterning process, which may simplify the manufacturing process of the display substrate 100.

The following description is made by taking an example in which the multiple data signal lines Data in a data signal group D are all located in the third wiring metal layer SD3, i.e., the plurality of data signal line groups D are all located in the third wiring metal layer SD3.

Since the multiple data signal lines Data are all located in the third wiring metal layer SD3, the number of the data signal lines Data may be increased. The following description is made by taking an example in which a data signal group D includes 4 data signal lines Data.

A data signal line group D includes 4 data signal lines Data extending in the column direction Y and arranged at intervals in the row direction X, and a column of pixel driving circuits Q are divided into 4 pixel driving circuit groups E.

The 4 data signal lines Data in the data signal line group D may be a first data signal line Data, a second data signal line Data, a third data signal line Data and a fourth data signal line Data. The 4 pixel driving circuit groups E in the column of pixel driving circuits Q may be a first pixel driving circuit group E, a second pixel driving circuit group E, a third pixel driving circuit group E and a fourth pixel driving circuit group E.

In this way, the first data signal line Data may be electrically connected to all the pixel driving circuits Q in the first pixel driving circuit group E, the second data signal line Data may be electrically connected to all the pixel driving circuits Q in the second pixel driving circuit group E, the third data signal line Data may be electrically connected to all the pixel driving circuits Q in the third pixel driving circuit group E, and the fourth data signal line Data may be electrically connected to all the pixel driving circuits Q in the fourth pixel driving circuit group E.

On this basis, any one of the first data signal line Data, the second data signal line Data, the third data signal line Data or the fourth data signal line Data is used to drive one pixel driving circuit group E. That is, 1 data signal line Data is used to drive part of the pixel driving circuits Q in a column of pixel driving circuits Q. Thus, it helps to increase the refresh duration of the pixel driving circuit Q, which may increase the time of threshold compensation for the pixel driving circuit Q to improve the effect of threshold compensation for the pixel driving circuit Q, so that the display uniformity of the display substrate 100 is improved. F is the refresh rate of the display substrate 100, and H is the number of rows of the pixel driving circuits Q in the display substrate 100.

In some examples, the number of pixel driving circuits Q in the first pixel driving circuit group E, the second pixel driving circuit group E, the third pixel driving circuit group E and the fourth pixel driving circuit group E is substantially the same, which is equivalent to that a column of pixel driving circuits Q are equally divided into 4 parts. On this basis, the refresh duration of the pixel driving circuit Q is approximately 4/FH; that is, the refresh duration of the pixel driving circuit Q is 4 times the above refresh duration 1/FH where the refresh duration of the pixel driving circuit Q is increased by 3 times, which may improve the effect of threshold compensation for the pixel driving circuit Q well, so as to improve the display uniformity of the display substrate 100.

In some examples, the 4 data signal lines Data included in a data signal line group D may be grouped in pairs, in which 2 data signal lines Data located on a side of a column of pixel driving circuits Q electrically connected to the data signal line group D and the other 2 data signal lines Data located on the other side of the column of pixel driving circuits Q electrically connected to the data signal line group D. On this basis, the spacing between the data signal lines Data may be increased to alleviate the problem of crosstalk between the data signal lines Data.

For example, the first data signal line Data is located between the third data signal line Data and the column of pixel driving circuits Q, the fourth data signal line Data is located between the second data signal line Data and the column of pixel driving circuits Q, and the embodiments of the present disclosure are not limited thereto.

It will be noted that, in the case where the driving circuit layer 20 includes the third wiring metal layer SD3, regardless of whether the data signal line Data is located in the second wiring metal layer SD2, the third wiring metal layer SD3, or the second wiring metal layer SD2 and third wiring metal layer SD3, the solutions described in the above embodiments are all applicable thereto; due to the different positions of the film layers, there may exist some additional conductive connecting portions for electrically connecting the pixel driving circuits Q to the respective signal line, and the details will not be elaborated here.

The above are only specific embodiments of the present disclosure, but the protection scope of the present disclosure is not limited thereto, and variations or substitutions that any person skilled in the art may conceive of within the technical scope of the present disclosure should fall within the protection scope of the present disclosure. Therefore, the protection scope of the present disclosure should be subjected to the protection scope of the claims.

1. A display substrate, comprising: a substrate and a driving circuit layer located on the substrate; wherein
the driving circuit layer includes:
a plurality of pixel driving circuits, wherein the plurality of pixel driving circuits are arranged in multiple rows and multiple columns, and a column of pixel driving circuits are divided into n pixel driving circuit groups;
a plurality of data signal line groups, wherein a data signal line group is electrically connected to the column of pixel driving circuits, the data signal line group includes n data signal lines extending in a column direction and arranged at intervals in a row direction, and a data signal line is electrically connected to all pixel driving circuits in a pixel driving circuit group;
wherein two adjacent columns of pixel driving circuits are an m-th column of pixel driving circuits and an (m+1)-th column of pixel driving circuits; a data signal line group electrically connected to the m-th column of pixel driving circuits includes at least one first data signal line, and a first data signal line of the at least one signal line is located between the m-th column of pixel driving circuits and the (m+1)-th column of pixel driving circuits; and a data signal line group electrically connected to the (m+1)-th column of pixel driving circuits includes at least one second data signal line, and a second data signal line of the at least one second data signal line is located between the m-th column of pixel driving circuits and the (m+1)-th column of pixel driving circuits; and
a plurality of anode transfer lines respectively electrically connected to driving output terminals of the plurality of pixel driving circuits, wherein multiple anode transfer lines electrically connected to the (m+1)-th column of pixel driving circuits include at least one first anode transfer line, and a first anode transfer line of the at least one first anode transfer line includes a first anode transfer portion in a same layer as the data signal line;
wherein in the row direction, the first anode transfer portion is located between the first data signal line electrically connected to the m-th column of pixel driving circuits and the second data signal line electrically connected to the (m+1)-th column of pixel driving circuits;
n is a positive integer greater than or equal to 2, and m is a positive integer.

2. The display substrate according to claim 1, further comprising:
an anode layer located on a side of the driving circuit layer away from the substrate, wherein the anode layer includes a plurality of anodes, the plurality of anodes include first anodes and second anodes, and the first anodes and the second anodes are alternately arranged in the column direction;
the first anode transfer portion extends in the column direction, and an orthographic projection of the first anode transfer portion on the substrate overlaps with an orthographic projection of a first anode of the first anodes on the substrate; the orthographic projection of the first anode transfer portion on the substrate overlaps with an orthographic projection of a second anode of the second anodes on the substrate, and the first anode transfer portion is electrically connected to the second anode.

3. The display substrate according to claim 2, wherein in the column direction, the orthographic projection of the first anode on the substrate and the orthographic projection of the second anode on the substrate are located between orthographic projections of two ends of the first anode transfer portion on the substrate.

4. The display substrate according to claim 2, wherein the data signal line group electrically connected to the m-th column of pixel driving circuits includes at least one third data signal line, and a third data signal line of the at least one third data signal line is located on a side of the m-th column of pixel driving circuits away from the (m+1)-th column of pixel driving circuits;
multiple anode transfer lines electrically connected to the m-th column of pixel driving circuits include at least one second anode transfer line, and a second anode transfer line of the at least one second anode transfer line includes a second anode transfer portion in the same layer as the data signal line; and
in the row direction, the second anode transfer portion is located on the side of the m-th column of pixel driving circuits away from the (m+1)-th column of pixel driving circuits.

5. The display substrate according to claim 4, wherein the second anode transfer portion extends in the column direction, and an orthographic projection of the second anode transfer portion on the substrate overlaps with the orthographic projection of the first anode on the substrate, the second anode transfer portion is electrically connected to the first anode, and the orthographic projection of the second anode transfer portion on the substrate overlaps with the orthographic projection of the second anode on the substrate.

6. The display substrate according to claim 5, wherein in the column direction, the orthographic projection of the first anode on the substrate and the orthographic projection of the second anode on the substrate are located between orthographic projections of two ends of the second anode transfer portion on the substrate.

7. The display substrate according to claim 2, wherein multiple columns of pixel driving circuits further include an (m+2)-th column of pixel driving circuits, and the (m+2)-th column of pixel driving circuits is located on a side of the (m+1)-th column of pixel driving circuits away from the m-th column of pixel driving circuits;
the data signal line group electrically connected to the (m+1)-th column of pixel driving circuits further includes at least one fourth data signal line, and a fourth data signal line of the at least one data signal line is located between the (m+1)-th column of pixel driving circuits and the (m+2)-th column of pixel driving circuits; a data signal line group electrically connected to the (m+2)-th column of pixel driving circuits includes at least one fifth data signal line, and a fifth data signal line of the at least one fifth data signal line is located between the (m+1)-th column of pixel driving circuits and the (m+2)-th column of pixel driving circuits;
multiple anode transfer lines electrically connected to the (m+2)-th column of pixel driving circuits include a third anode transfer line, and the third anode transfer line includes a third anode transfer portion in the same layer as the data signal line; and
in the row direction, the third anode transfer portion is located between the fourth data signal line electrically connected to the (m+1)-th column of pixel driving circuits and the fifth data signal line electrically connected to the (m+2)-th column of pixel driving circuits.

8. The display substrate according to claim 7, wherein the plurality of anodes further include third anodes, and in the row direction, a third anode overlaps with the first anode, and the third anode overlaps with the second anode;
the third anode transfer portion extends in the column direction; in the column direction, a border of an orthographic projection of the third anode transfer portion on the substrate overlaps with a border of an orthographic projection of the third anode on the substrate, and the third anode transfer portion is electrically connected to the third anode.

9. The display substrate according to claim 8, wherein in the column direction, the orthographic projection of the third anode on the substrate is located between orthographic projections of two ends of the third anode transfer portion on the substrate.

10. The display substrate according to claim 1, wherein in a same column of pixel driving circuits, a number of pixel driving circuits in each pixel driving circuit group is same.

11. The display substrate according to claim 1, wherein multiple data signal lines in the data signal line group are divided into a first part of data signal lines and a second part of data signal lines, and the first part of data signal lines and the second part of data signal lines are respectively located on two sides of the column of pixel driving circuits electrically connected the data signal line group, and
a number of data signal lines of the first part is equal to a number of data signal lines of the second part.

12. The display substrate according to claim 11, wherein the pixel driving circuit includes a driving transistor, a data writing transistor, a data transfer portion and a first light-emitting control transistor; a first electrode of the driving transistor and a second electrode of the data writing transistor are electrically connected to a second electrode of the first light-emitting control transistor, and a first electrode of the data writing transistor is electrically connected to a data signal line in the data signal line group through the data transfer portion; and
in the column direction, the data writing transistor is located on a side of the first light-emitting control transistor away from the driving transistor, and the first electrode of the data writing transistor is located on a side of the data writing transistor away from the first light-emitting control transistor.

13. The display substrate according to claim 12, wherein the pixel driving circuit further includes a second light-emitting control transistor and a second reset transistor, and a second electrode of the second light-emitting control transistor is electrically connected to a second electrode of the second reset transistor; and
in the column direction, the second reset transistor is located on a side of the second light-emitting control transistor away from the driving transistor; in the row direction, the second light-emitting control transistor is adjacent to the first light-emitting control transistor, and the second reset transistor is adjacent to the data writing transistor.

14. The display substrate according to claim 13, wherein the column of pixel driving circuits include a first part of pixel driving circuits electrically connected to the second part of data signal lines and a second part of pixel driving circuits electrically connected to the first part of data signal lines;
a data writing transistor of the first part of pixel driving circuits is located between a second reset transistor of the first part of pixel driving circuits and the second part of data signal lines, and a data writing transistor of the second part of pixel driving circuits is located on a side of a second reset transistor of the second part of pixel driving circuits away from the first part of data signal lines; and
at least one pixel driving circuit in the second part of pixel driving circuits includes a first data transfer portion, and in a pixel driving circuit including the first data transfer portion, the first data transfer portion is electrically connected to a first electrode of a data writing transistor and a data signal line; the first data transfer portion includes an avoiding portion, and the avoiding portion is located on a side of a second reset transistor away from a second light-emitting control transistor in the pixel driving circuit including the first data transfer portion.

15. The display substrate according to claim 14, wherein the driving circuit layer further includes:
a second initialization signal line, wherein the second initialization signal line includes a first connecting portion, and a first electrode of the second reset transistor is electrically connected to the first connecting portion of the second initialization signal line;
wherein in the column direction, the second initialization signal line is located on a side of the second reset transistor away from the second light-emitting control transistor, and the avoiding portion is located on a side of the first connecting portion away from the second light-emitting control transistor.

16. The display substrate according to claim 14,
wherein the driving circuit layer further includes a plurality of first power signal lines extending in the column direction and arranged in the row direction, and a first power signal line is electrically connected to the pixel driving circuit; and
in the row direction, the first part of data signal lines and the second part of data signal lines are respectively located on two sides of the first power signal line.

17. The display substrate according to claim 16, wherein the avoiding portion crosses over a first power signal line electrically connected to the second part of pixel driving circuits.

18. The display substrate according to claim 11, wherein the data signal line group includes two data signal lines; and
the driving circuit layer includes a first semiconductor layer, a first gate metal layer, a second gate metal layer, a first wiring metal layer and a second wiring metal layer that are arranged in sequence on the substrate; the two data signal lines in the data signal line group are both located in the second wiring metal layer.

19. The display substrate according to claim 11, wherein the data signal line group includes four data signal lines;
the driving circuit layer further includes a first semiconductor layer, a first gate metal layer, a second gate metal layer, a first wiring metal layer, a second wiring metal layer and a third wiring metal layer that are arranged in sequence on the substrate; and
at least a part of data signal lines in the data signal line group is located in the second wiring metal layer, and/or at least a part of data signal lines in the data signal line group is located in the third wiring metal layer.

20. A display device, comprising the display substrate according to claim 1.
